(19) United States
(12) Patent Application Publication
(10) Pub. No.: US 2007/0249098 A1
(43) Pub. Date: Oct. 25, 2007

(54) Bonding plate mechanism for use in anodic bonding

(76) Inventors: Raymond Charles Cady, Horseheads, NY (US); Alexander Lakota, Kanona, NY (US); William Edward Lock, Horseheads, NY (US); John Christopher Thomas, Elmira, NY (US); John Joseph Costello, Lake Elmo, MN (US)

Correspondence Address: CORNING INCORPORATED, SP-TI-3-1, CORNING, NY, 14831, US

(21) Appl. No.: 11/786,307

(22) Filed: Apr. 11, 2007

Related U.S. Application Data
(60) Provisional application No. 60/793,976, filed on Apr. 21, 2006.

(51) Int. Cl. H01L 21/00; H01L 21/30

(52) U.S. Cl. 438/119; 438/455

(57) ABSTRACT

A bonding plate mechanism for use in anodic bonding of first and second material sheets together, the apparatus comprising: a base including first and second spaced apart surfaces; a thermal insulator supported by the second surface of the base and operable to impede heat transfer to the base; a heating disk directly or indirectly coupled to the insulator and operable to produce heat in response to electrical power; and a thermal spreader directly or indirectly coupled to the heating disk and operable to at least channel heat from the heating disk, and impart voltage, to the first material sheet, wherein the heat and voltage imparted to the first material sheet are in accordance with respective heating and voltage profiles to assist in the anodic bonding of the first and second material sheets, and a thermal inertia of the bonding plate mechanism is relatively low such that heating of the first material sheet to a temperature of about 600° C. or greater is achieved in less than about one-half hour.

### BACKGROUND

The present invention relates to an apparatus for manufacturing, for example, a semiconductor-on-insulator (SOI) structure using an anodic bonding technique.

To date, the semiconductor material most commonly used in semiconductor-on-insulator structures has been silicon, and the abbreviation “SOI” has been applied to such structures. SOI technology is becoming increasingly important for high performance thin film transistors, solar cells, and displays, such as, active matrix displays.

For ease of presentation, the following discussion will at times refer to SOI structures, however, such references to this particular type of structure are made to facilitate the explanation of the invention and are not intended to, and should not be interpreted as, limiting the invention's scope in any way. The SOI abbreviation is used herein to refer to semiconductor-on-insulator structures in general, including, but not limited to, silicon-on-insulator structures. Similarly, the SOG abbreviation is used to refer to semiconductor-on-glass structures in general, including, but not limited to, silicon-on-glass structures. The SOG nomenclature is also intended to include semiconductor-on-glass-ceramic structures, including, but not limited to, silicon-on-glass-ceramic structures. The abbreviation SOI encompasses SOG structures.

SOI structures may include a thin layer of substantially single crystal silicon (generally 0.1-0.3 microns in thickness) on an insulating material. Various ways of obtaining SOI structures include: (i) bonding a single crystal silicon wafer to another silicon wafer on which an oxide layer of SiO₂ has been grown; (ii) ion-implantation methods to form a buried oxide layer in the silicon wafer; (iii) ion-implantation methods to separate (exfoliate) a thin silicon layer from a silicon donor wafer and bond same to another silicon wafer.

U.S. Pat. No. 5,374,564 discloses a process for obtaining a single crystal silicon film on a substrate using a thermal process. A semiconductor donor wafer having a planar face is subject to the following steps: (i) implantation by bombardment of a face of the wafer by means of ions creating a layer of gaseous micro-bubbles defining a lower region constituting the mass of the donor wafer and an upper region constituting a relatively thin exfoliation layer; (ii) contacting the planar face of the wafer with a stiffener constituted by at least one rigid material layer; and (iii) a third stage of heat treating the assembly of the wafer and the stiffener at a temperature above that at which the ion bombardment was carried out and sufficient to create a pressure effect in the micro-bubbles and a separation between the thin film and the mass of the substrate. Notably, this process does not generally work with glass or glass-ceramic substrates because much higher temperatures are required for bonding some glass and glass-ceramic substrates.

U.S. Patent Application No. 2004/0229444 discloses a process that produces a SOG structure, the entire disclosure of which is hereby incorporated by reference. The steps include: (i) exposing a silicon donor wafer surface to hydrogen ion implantation to create an exfoliation layer having a bonding surface; (ii) bringing the bonding surface of the silicon donor wafer into contact with a glass substrate; (iii) applying pressure, temperature and voltage to the silicon donor wafer and the glass substrate to facilitate bonding therebetween; and (iv) cooling the structure to a common temperature to facilitate separation of the glass substrate and the exfoliation layer of silicon from the silicon donor wafer.

The SOG structure resulting from the process disclosed in U.S. Patent Application No. 2004/0229444 may include, for example, a glass substrate, and a semiconductor layer bonded thereto. The specific material of the semiconductor layer may be in the form of a substantially single-crystal material. The word “substantially” is used in describing the semiconductor layer to take account of the fact that semiconductor materials normally contain at least some internal or surface defects either inherently or purposely added, such as lattice defects or a few grain boundaries. The word “substantially” also reflects the fact that certain dopants may distort or otherwise affect the crystal structure of bulk semiconductor.

For the purposes of discussion, it may be assumed that the semiconductor layers discussed herein may be formed from silicon. It is understood, however, that the semiconductor material may be a silicon-based semiconductor or any other type of semiconductor, such as, the III-V, II-IV, II-IV-V, etc. classes of semiconductors. Examples of these materials include: silicon (Si), germanium-doped silicon (SiGe), silicon carbide (SiC), germanium (Ge), gallium arsenide (GaAs), GaP, and InP. The glass substrate may be formed from an oxide glass or an oxide glass-ceramic. Although not required, the SOG structures described herein may include an oxide glass or glass-ceramic. By way of example, the glass substrate may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE 2000™. These glass materials have particular use in, for example, the production of liquid crystal displays.

It has been discovered by the present inventors that a good quality anodic bond between the thin exfoliation semiconductor layer (e.g., silicon) and certain substrates, such as some glass and glass ceramic substrates, requires careful control of a number of process variables. These variables include one or more of: temperature (especially high temperatures approaching and/or exceeding 1000° C.); pressure (between the semiconductor layer and the substrate); voltage (to induce electrolysis); atmospheric conditions (e.g., vacuum or non-vacuum); cooling profiles (to induce exfoliation); mechanical separation enhancement (e.g., to assist in exfoliation); etc. Conventional techniques for the anodic bonding of a semiconductor layer to a glass or glass-ceramic substrate do not adequately address the above process variables. For example, the temperature limit of conventional anodic bonding processes is about 600° C.

Thus, there are needs in the art for new apparatuses that can achieve improvement in the anodic bonding process, e.g., by controlling one or more of the process variables above.

### SUMMARY OF THE INVENTION

In accordance with one or more embodiments of the present invention, an anodic bonding apparatus includes: a first bonding plate mechanism operable to engage a first material sheet, and to provide at least one of controlled heating, voltage, and cooling thereto; a second bonding plate mechanism operable to engage a second material sheet, and to provide at least one of controlled heating, voltage, and cooling thereto; a pressure mechanism operatively coupled to the first and second bonding plate mechanisms and operable to urge the first and second bonding plate mechanisms toward one another to achieve controlled pressure of the first and second material sheets against one another along respective surfaces thereof, a control unit operable to produce control signals to the first and second bonding plate mechanisms and the pressure mechanism to provide heating, voltage, and pressure profiles sufficient to achieve anodic bonding between the first and second material sheets.

In accordance with one or more further embodiments of the present invention, an anodic bonding apparatus includes: a first bonding plate mechanism operable to engage a first material sheet, and to provide at least one of controlled heating and voltage thereto; a second bonding plate mechanism operable to engage a second material sheet, and to provide at least one of controlled heating and voltage thereto; and a lift and press mechanism operatively coupled to the first bonding plate mechanism and operable to urge the first and second bonding plate mechanisms toward one another to achieve controlled pressure of the first and second material sheets against one another along respective surfaces thereof to assist in the anodic bonding of same.

In accordance with one or more further embodiments of the present invention, an anodic bonding apparatus includes: a first bonding plate mechanism operable to engage a first material sheet and a second bonding plate mechanism operable to engage a second material sheet, the first and second bonding plate mechanisms each including a bearing surface, each bearing surface defining a bearing plane for engaging a respective one of the first and second material sheets; and an open and close mechanism operatively coupled to the second bonding plate mechanism and operable to: (i) assist, when in a closed orientation, in holding the upper bonding plate mechanism in position with respect to the lower bonding plate mechanism such that movement of the lower bonding plate mechanism toward the upper bonding plate mechanism achieves controlled pressure of the first and second material sheets against one another along respective surfaces thereof; and (ii) provide a dual motion opening profile, where a first motion separates the second bonding plate mechanism from the first bonding plate mechanism in a direction substantially perpendicular to the respective bearing planes thereof, and a second motion tilts the second bonding plate mechanism away from the first bonding plate mechanism such that the bearing plane of the second bonding plate mechanism is oblique to the bearing plane of the first bonding plate mechanism.

In accordance with one or more further embodiments of the present invention, an anodic bonding apparatus includes: a first bonding plate mechanism operable to engage the first material sheet, and to provide at least one of controlled heating, voltage, and cooling thereto; a second bonding plate mechanism operable to engage the second material sheet, and to provide at least one of controlled heating, voltage, and cooling thereto,; and a spacer mechanism including a plurality of movable shim assemblies, the spacer mechanism being coupled to the first bonding plate mechanism, and being operable to symmetrically move the shim assemblies toward and between the first and second material sheets to prevent peripheral edges of the first and second material sheets from touching one another.

In accordance with one or more further embodiments of the present invention, a bonding plate mechanism (for use in anodic bonding of first and second material sheets together) includes: a base including first and second spaced apart surfaces; a thermal insulator supported by the second surface of the base and operable to impede heat transfer to the base; a heating disk directly or indirectly coupled to the insulator and operable to produce heat in response to electrical power; and a thermal spreader directly or indirectly coupled to the heating disk and operable to at least channel heat from the heating disk, and impart voltage, to the first material sheet, wherein the heat and voltage imparted to the first material sheet are in accordance with respective heating and voltage profiles to assist in the anodic bonding of the first and second material sheets.

In accordance with one or more further embodiments of the present invention, a bonding plate mechanism (for use in anodic bonding of first and second material sheets together) includes: a base including first and second spaced apart surfaces; a heating disk directly or indirectly coupled to the base and operable to produce heat in response to electrical power, wherein the heater disk includes a plurality of heating zones operable to provide an edge loss temperature compensation feature, wherein the heat imparted to the first material sheet is in accordance with a heating profile to assist in the anodic bonding of the first and second material sheets.

In accordance with one or more further embodiments of the present invention, a bonding plate mechanism (for use in anodic bonding of first and second material sheets together) includes: a heating disk including first and second spaced apart surfaces and operable to produce heat in response to electrical power; a thermal spreader directly or indirectly coupled to the second surface of the heating disk and operable to at least channel heat from the heating disk, and impart voltage, to the first material sheet; and at least one cooling channel in thermal communication with the first surface of the heater disk and being operable to carry cooling fluid to remove heat from the first material sheet through the thermal spreader and heater disk, wherein the heat and voltage imparted to the first material sheet are in accordance with respective heating and voltage profiles to assist in the anodic bonding of the first and second material sheets, and the cooling imparted to the first material sheet is in accordance with a cooling profile to assist in separating, from the first material sheet, an exfoliation layer that has been bonded to the second material sheet.

In accordance with one or more further embodiments of the present invention, a bonding plate mechanism (for use in anodic bonding of first and second material sheets together) includes: a base including first and second spaced apart surfaces and an aperture therethrough; a heating disk supported by, and thermally insulated from, the base and operable to produce heat in response to electrical power, the heating disk including an aperture therethrough; a thermal spreader directly or indirectly coupled to the heating disk and operable to at least channel heat from the heating disk, and impart a bonding voltage, to the first material sheet, the thermal spreader including an aperture therethrough; and a preload plunger having an electrode extending through the apertures of the base, the heating disk, and the thermal spreader, the electrode being operable to electrically connect to the first material sheet when it contacts the thermal spreader.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a perspective view of an embodiment of the bonding apparatus of the present invention in a partially closed configuration;

FIG. 2 is a front elevational view of the bonding apparatus of FIG. 1 in an open configuration;

FIG. 3 is a front elevational view of the bonding apparatus of FIG. 1 in a partially closed configuration;

FIG. 4A is a front elevational view of the bonding apparatus of FIG. 1 in a closed configuration;

FIG. 4B is a side elevational view of the bonding apparatus of FIG. 1 in a closed configuration;

FIG. 5 is a partially exploded perspective view of the bonding apparatus of FIG. 1;

FIG. 6 is a perspective view of an embodiment of a lift and press mechanism suitable for use in the bonding apparatus of FIG. 1 (and/or one or more other embodiments);

FIG. 7 is a perspective view of an embodiment of an open and close mechanism suitable for use in the bonding apparatus of FIG. 1 (and/or one or more other embodiments);

FIG. 8A is a perspective view of an embodiment of an upper (or lower) bonding plate mechanism suitable for use in the bonding apparatus of FIG. 1 (and/or one or more other embodiments);

FIG. 8B is a cross-sectional view of the bonding plate mechanism of FIG. 8A taken through line 8B-8B;

FIG. 9A is a perspective view of a heater element suitable for use with the upper (or lower) bonding plate mechanism of FIG. 8A or other embodiments;

FIG. 9B is a perspective view of an alternative heater element suitable for use with the upper (or lower) bonding plate mechanism of FIG. 8A or other embodiments;

FIG. 10 is an exploded perspective view of the bonding plate mechanism of FIG. 8A;

FIG. 11A is a top plan view of the bonding plate mechanism of FIG. 8A;

FIG. 11B is a cross-sectional view of the bonding plate mechanism of FIG. 11A taken though line 11B-11B;

FIG. 11C is a cross-sectional view of the bonding plate mechanism of FIG. 11A taken though line 11C-11C;

FIG. 12A is a side elevational view of a preload plunger suitable for use with the bonding plate mechanism of FIG. 8A (and/or one or more other embodiments);

FIG. 12B is a cross-sectional view of the preload plunger of FIG. 12A taken though line 12B-12B;

FIG. 13 is a cross-sectional view of upper and lower bonding plate mechanisms suitable for use in the bonding apparatus of FIG. 1 (and/or one or more other embodiments);

FIG. 14 is a perspective view of an embodiment of a spacer mechanism suitable for use in the bonding apparatus of FIG. 1 (and/or one or more other embodiments);

FIG. 15 is an exploded view of a thermocouple in a pre-loaded mounting fixture suitable for use with the bonding plate mechanism of FIG. 8A (and/or one or more other embodiments);

FIG. 16 is a perspective view of an alternative embodiment of an upper (or lower) bonding plate mechanism suitable for use in the bonding apparatus of FIG. 1 (and/or one or more other embodiments);

FIG. 17 is an exploded view of the bonding plate mechanism of FIG. 16;

FIG. 18 is an exploded view of a heater disk suitable for use with the bonding plate mechanism of FIG. 16 (and/or one or more other embodiments);

FIG. 19 is a cross-sectional view of the bonding plate mechanism of FIG. 16;

FIG. 20 is a cross-sectional view of an alternative embodiment of an upper (or lower) bonding plate mechanism suitable for use in the bonding apparatus of FIG. 1 (and/or one or more other embodiments);

FIG. 21 is an exploded perspective view of the bonding plate mechanism of FIG. 20;

FIG. 22 is a side elevational view of the bonding apparatus of FIG. 1 disposed within an atmospheric control chamber;

FIG. 23 is a block diagram illustrating the structure of an SOG device that may be produced using the bonding apparatus of FIG. 1;

FIGS. 24-26 are block diagrams illustrating intermediate structures that may be formed and/or operated upon using the bonding apparatus of FIG. 1;

FIG. 27 is a block diagram illustrating a final SOG structure that may be formed using the bonding apparatus of FIG. 1; and

FIG. 28 is a block diagram of the bonding apparatus of FIG. 1 adapted for a micro-structure embossing application.

### DETAILED DESCRIPTION OF THE PRESENT INVENTION

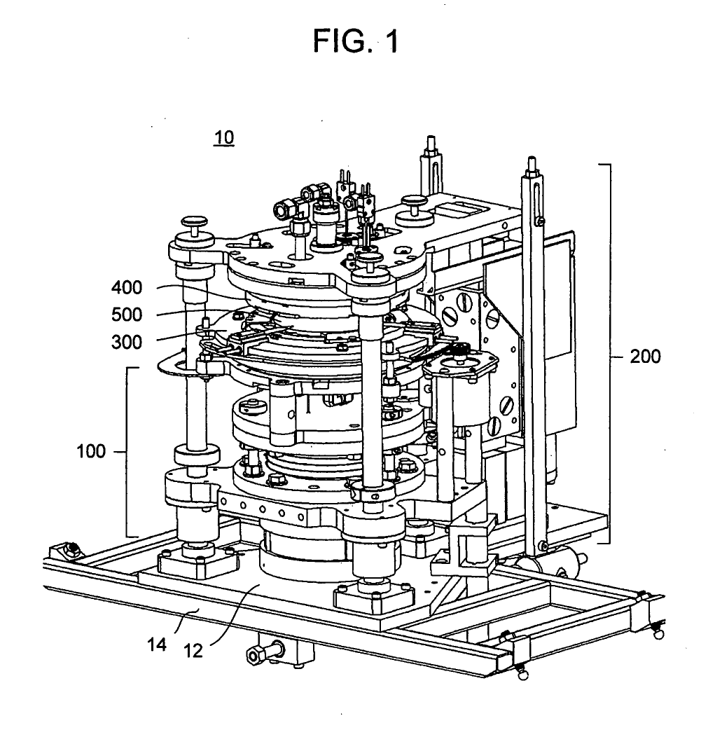

With reference to the drawings, wherein like numerals indicate like elements, there is shown in FIG. 1 a perspective view of a bonding apparatus 10 in accordance with one or more embodiments of the present invention. In this embodiment, the bonding apparatus is an integrated processing system capable of anodically bonding two material sheets of an SOI structure at temperatures above conventional bonding temperatures, e.g., above 600° C. and approaching and/or exceeding 1000° C. (It is noted that the bonding apparatus 10 is also capable of anodic bonding at conventional temperatures.) For purposes of illustration (but not limitation), an SOI structure will be described herein as a suitable work piece upon which the bonding apparatus 10 operates (e.g., in producing the SOI structure). Also for purposes of discussion (but not limitation), the particular SOI structure discussed hereinbelow as a work piece will be an SOG structure formed by bonding a semiconductor donor wafer (such as a silicon wafer) to a glass (or glass ceramic) substrate and exfoliating a silicon layer from the silicon donor wafer such that it remains bonded to the glass substrate.

The bonding apparatus 10 includes the following components: a lift and press mechanism 100, an open and close mechanism 200, a spacer mechanism 300, an upper bonding plate mechanism 400, and a lower bonding plate mechanism 500. These main components are coupled to one another and the combination is supported by a base plate 12 and support frame 14. A control unit (not shown), which may include one or more closed control loops, is operable to control the various elements of the bonding apparatus 10 (e.g., by way of a computer program) as will be discussed in more detail below.

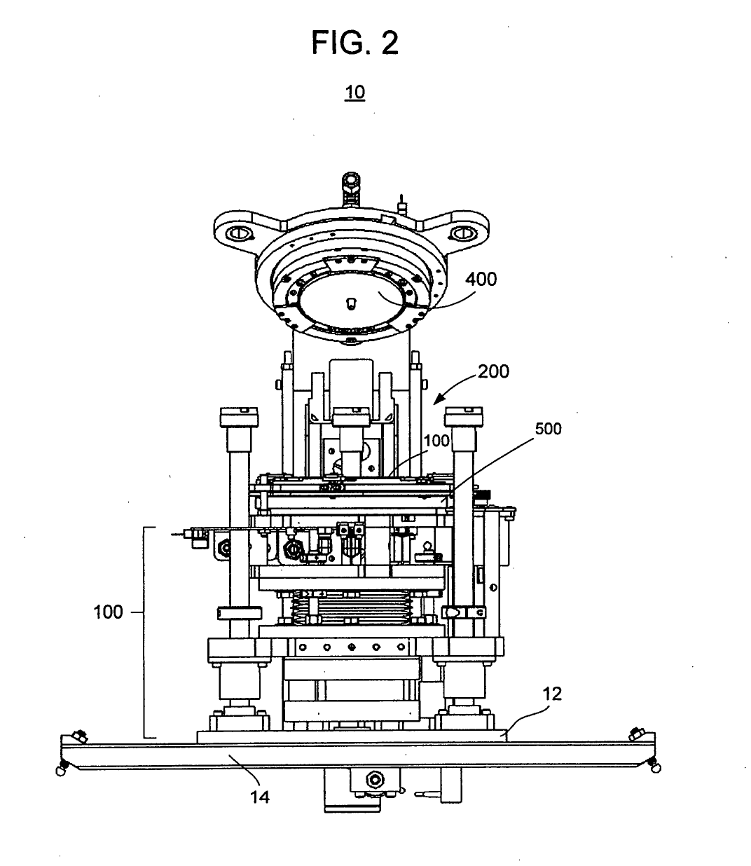

Although the operation of the bonding apparatus 10 and certain specific bonding processes will be described in more detail later in this document, a brief introduction of such operation will now be presented. In FIG. 1, the bonding apparatus 10 is in a closed orientation whereby the upper bonding plate mechanism 400 closely overlies the lower bonding plate mechanism 500. As seen in FIG. 2, the upper bonding plate mechanism 400 is operable to rotate upward and away from the lower bonding plate mechanism 500 to permit insertion of the two material sheets (e.g., a silicon donor wafer and a glass substrate) to be bonded together into the apparatus 10. Again, for the purposes of discussion, the silicon donor wafer is assumed to include an exfoliation layer to be bonded to the glass substrate and later separated from the silicon donor wafer.

In this example, it is assumed that the silicon donor wafer contacts the upper bonding plate mechanism 400, while the glass substrate contacts the lower bonding plate mechanism 500 during the bonding process. For example, the glass substrate may be set down on the lower bonding plate mechanism 500 and the silicon donor wafer may be set atop the glass substrate so that it will be in a position to contact the upper bonding plate mechanism 400 (when the apparatus 10 is closed). (It is understood, however that this orientation may be reversed without departing from the scope of various embodiments of the invention.) In alternative embodiments, the silicon donor wafer may be coupled to the upper bonding plate mechanism 400, for example by clips, chuck mechanisms, vacuum, etc. when the upper bonding plate mechanism 400 is in the open position.

In general, the upper bonding plate mechanism 400 is operable to provide at least one of controlled heating, voltage, and cooling to the silicon donor wafer, while the lower bonding plate mechanism 500 is operable to provide at least one of controlled heating, voltage, and cooling to the glass substrate. The lift and press mechanism 100 is operatively coupled to the upper and lower bonding plate mechanisms 400, 500 and is operable to urge the first and second bonding plate mechanisms 400, 500 toward one another to achieve controlled pressure of the silicon donor wafer against the glass substrate along respective surfaces (i.e., an interface) thereof. The control unit is operable to produce control signals to the upper and lower bonding plate mechanisms 400, 500 and the lift and press mechanism 100 to provide heating, voltage, and pressure profiles sufficient to achieve anodic bonding between the silicon donor wafer and the glass substrate. The control unit is also operable to produce control signals to the upper and/or the lower bonding plate mechanisms 400, 500 to actively cool same and facilitate separation of the exfoliation layer from the silicon donor wafer after bonding.

As shown in FIG. 2, after the upper bonding plate mechanism 400 rotates upward and away from the lower bonding plate mechanism 500 and the silicon donor wafer and the glass substrate are inserted therebetween, the upper bonding plate mechanism 400 is operable to rotate downward (via the open and close mechanism 200) such that the upper and lower bonding plate mechanisms 400, 500 are spaced apart. Thus, when the silicon donor wafer is set atop the glass substrate, the upper bonding plate mechanism 400 will be spaced apart from the silicon donor wafer. Alternatively, if the silicon donor wafer is coupled to the upper bonding plate mechanism 400 (e.g., by the aforementioned clips, chuck, vacuum, etc.), the silicon donor wafer and the glass substrate will be spaced apart. If the latter approach is employed, separate heating of the silicon donor wafer and the glass substrate to specific temperatures (which may approach and/or exceed 1000° C.) may commence by way of controlled energizing of the respective upper and lower bonding plate mechanisms 400, 500. If the former approach is employed, separate heating may commence after full closure of the bonding apparatus 10.

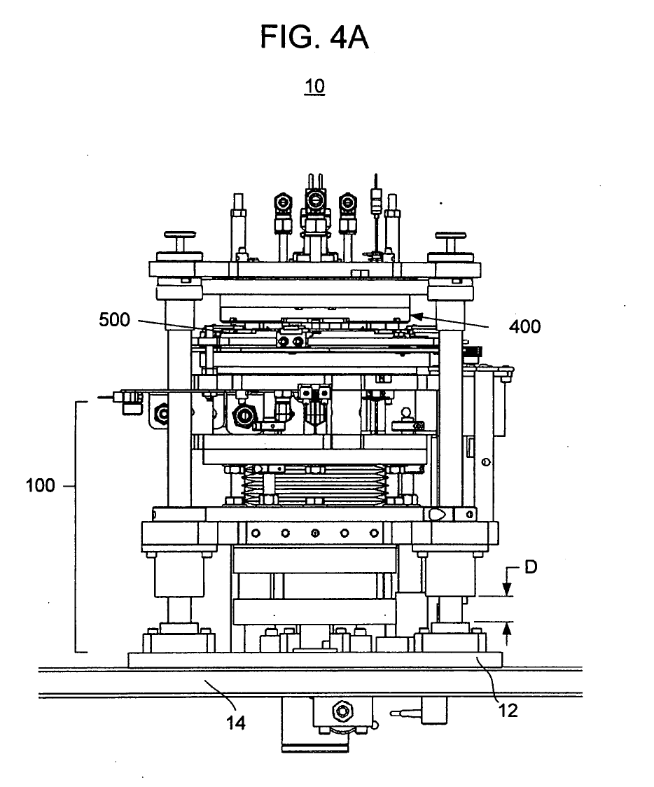

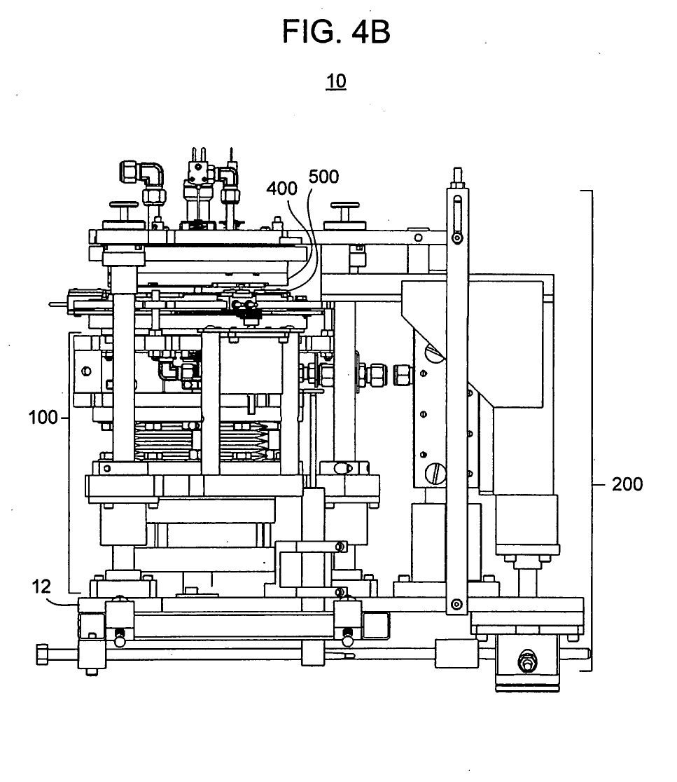

As shown in FIGS. 4A and 4B, the silicon donor wafer and the glass substrate may contact one another under the controlled actuation of the lift and press mechanism 100. The lift and press mechanism 100 raises the lower bonding plate mechanism 500 (and the glass substrate) into position such that controlled heating and pressure between the silicon donor wafer and the glass substrate may be achieved. The silicon donor wafer and the glass substrate are also subject to a differential voltage potential of about 1750 volts DC imposed by the respective upper and lower bonding plate mechanisms 400, 500. The pressure, temperature differential, and voltage differential are applied for a controlled period of time. Thereafter, the voltage is brought to zero and the silicon donor wafer and the glass substrate are permitted to cool (which may involve active cooling), which at least initiates the separation of the exfoliation layer from the silicon donor wafer. Although not believed likely, if the separation between the exfoliation layer and the silicon donor wafer is not complete from the cooling process, one or more mechanical or other mechanisms may be used to assist in the exfoliation process.

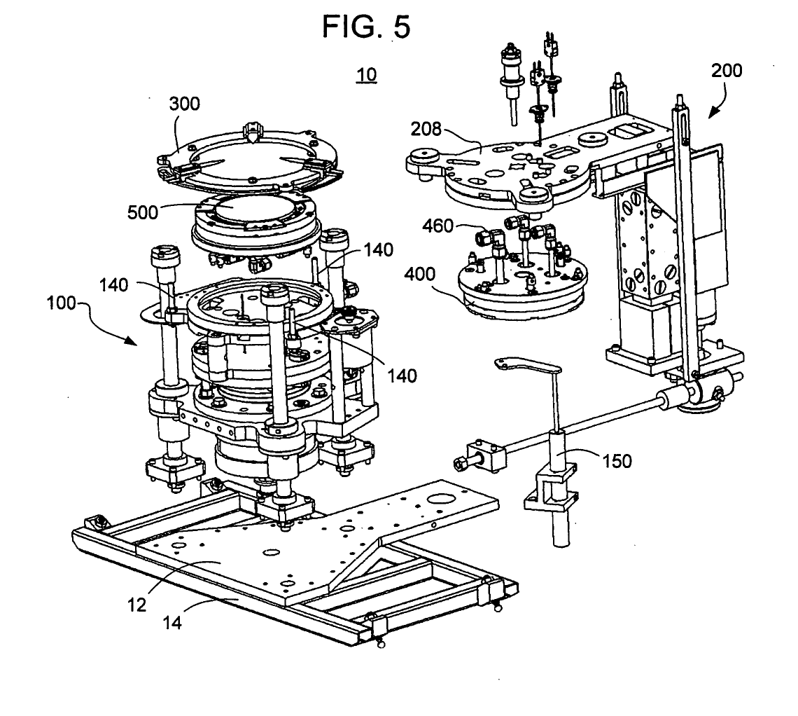

A more detailed discussion of the respective elements of the bonding apparatus 10 will now be described. FIG. 5 is a perspective, partially exploded, view of the bonding apparatus 10. Thus, the specific components of the lift and press mechanism 100, the open and close mechanism 200, the spacer mechanism 300, and the upper and lower bonding plate mechanisms 400, 500 are easily discerned.

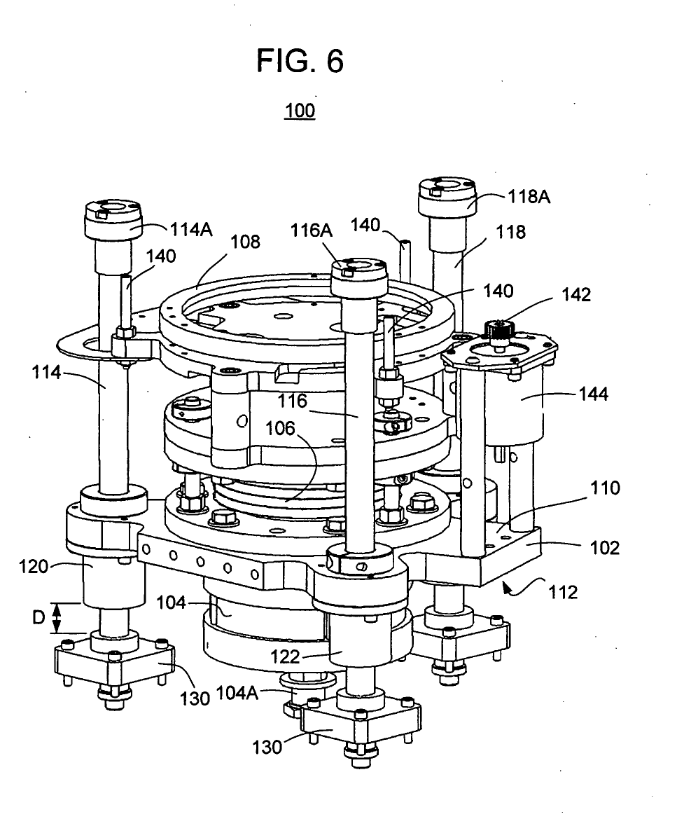

With further reference to FIG. 6, an embodiment of the lift and press mechanism 100 will now be discussed. The lift and press mechanism 100 is coupled to the lower bonding plate mechanism 500 and is operable to urge the upper and lower bonding plate mechanisms 400, 500 toward one another to achieve controlled pressure of the silicon donor wafer and the glass substrate against one another along respective surfaces thereof to assist in the anodic bonding of same. In this embodiment, the lift and press mechanism 100 is operable to permit two basic movements of the lower bonding plate mechanism 500: (i) pre-loading movement in which the lower bonding plate mechanism 500 moves the glass substrate vertically toward the upper bonding plate mechanism 400 to achieve initial pre-load positioning of the upper and lower bonding plate mechanisms 400, 500 (and thus the glass substrate and the silicon donor wafer); and (ii) pressure loading movement in which the glass substrate is pressed against the silicon donor wafer at a controlled pressure (which may also permit self-alignment between the glass substrate and the silicon donor wafer for substantially uniform pressure distribution).

The lift and press mechanism 100 includes a base 102, a first actuator 104, a second actuator 106, and a lower mount 108. The base 102 includes an upper surface 110 and a lower surface 112. The first actuator 104 may be coupled to the lower surface 112 of the base 102, while the second actuator 106 may be coupled to the upper surface 110 of the base 102. The lower mount 108 is coupled to the second actuator 106 such that the second actuator 106 is interposed between the base 102 and the lower mount 108.

The base 102 is slideable with respect to a plurality of guide posts 114, 116, 118. (Although three guide posts are shown, a lesser or greater number of guide posts may be employed.) By way of example, the base 102 may include respective guide bushings 120, 122, 124 (where bushing 124 is not visible), whereby the respective guide posts 114, 116, 118 are coaxially disposed within the respective guide bushings 120, 122, 124 such that the guide posts 114, 116, 118 may slide longitudinally within the guide bushings 120, 122, 124. The respective guide posts 114, 116, 118 may be anchored to the base plate 12 of the bonding apparatus 10 by way of fasteners 130.

In accordance with one or more embodiments, actuation of the first actuator 104 may achieve the aforementioned pre-loading movement in which the lower bonding plate mechanism 500 moves via the lower mount 108 toward the upper bonding plate mechanism 400 to achieve initial pre-load positioning of the upper and lower bonding plate mechanisms 400, 500 (and thus the glass substrate and the silicon donor wafer). This pre-load movement may be a coarse displacement of the lower bonding plate mechanism 500 toward the upper bonding plate mechanism 400. The first actuator 104 and the second actuator 106 may be mounted in axial alignment with the lower bonding plate mechanism 500 such that the actuation of the first actuator 104 imparts the coarse displacement of both the second actuator 106 and the lower bonding plate mechanism 500.

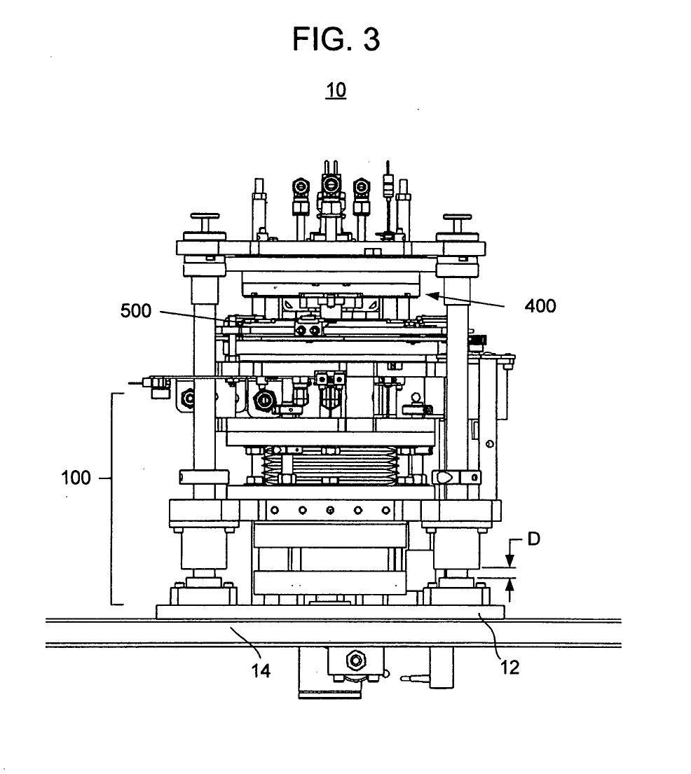

More particularly, the first actuator 104 may include a shaft 104A that is operable to move the first actuator 104 upward and downward. The shaft 104A may be driven by way of any suitable device, such as an electromechanical solenoid, a hydraulic piston arrangement, etc. Upward and downward movement of the first actuator 104 may cause corresponding movement of the base 102, whereby the planar orientation of the base 102 is maintained by way of the guide posts 114, 116, 118 as they slide within the guide bushings 120, 122, 124. The movement of the base 102 results in corresponding movements of the second actuator 106, the lower mount 108, and the lower bonding plate mechanism 500. The movement of the first actuator 104 by way of the shaft 104A may be mechanically, electrically, and/or hydraulically limited such that the pre-loading movement of the lower bonding plate mechanism 500 is controlled. As shown in FIG. 6, the limited movement may be measured by the distance D between the respective fasteners 130 and the guide bushings 120, 122, 124 as compared with a substantially zero or resting distance therebetween as illustrated in FIG. 3.

The second actuator 106 of the lift and press mechanism 100 is operable to impart a controllable force (e.g., fine movement as compared with the aforementioned coarse movement) on the lower bonding plate mechanism 500, where the controllable force is substantially perpendicular to the bearing surface (i.e., the surface that contacts the glass substrate) of the lower bonding plate mechanism 500. As the bearing surface of the upper bonding plate mechanism 400 is parallel to the bearing surface of the lower bonding plate mechanism 500, the second actuator 106 of the lift and press mechanism 100 ensures that no (or minimal) lateral forces are applied as between the silicon donor wafer and the glass substrate, which might cause scraping or other impediments to the quality of the anodic bond.

The second actuator 106 may be a bellows actuator that is operable to move the lower mount 108 upward and downward in response to changing the internal fluid pressure (e.g., liquid or gas pressure) of the bellows. The second actuator 106 may be independently controlled (with respect to the first actuator 104) in order to achieve the aforementioned pressure loading movement in which the glass substrate is pressed against the silicon donor wafer. Careful control of the second actuator 106 by way of the control unit (e.g., control of the pressure within the bellows) may be employed to establish the proper pressure (psi) as between the glass substrate and the silicon donor wafer for anodic bonding. Further, employing a bellows in second actuator 106 permits the lower mount 108, the lower bonding plate mechanism 500, and the glass substrate to float or self-align with respect to the upper bonding plate mechanism 400 (and the silicon donor wafer).

The lift and press mechanism 100 may also include a plurality of mounting elements, such as upwardly directed posts 140 that are coupled to the lower mount 108. The mounting elements 140 are operable to engage and retain the spacer mechanism 300 as will be discussed in more detail later in this description.

As best seen in FIG. 5, the lift and press mechanism 100 may also include a position sensor 150 coupled to the lower mount 108 and/or the lower bonding plate mechanism 500. The position sensor 150 is operable to provide an output signal to the control mechanism indicating to what extent the lower bonding plate mechanism 500 has been moved. For example, the output signal of the position sensor 150 may provide an indication of whether the aforementioned coarse displacement of the lower bonding plate mechanism 500 (toward the upper bonding plate mechanism 400) has taken place. This may provide an indication of when to initiate heating, preload pressure and seed voltage application, etc. The output signal of the position sensor 150 may additionally or alternatively provide an indication of the velocity and/or acceleration of the lower bonding plate mechanism 500. Those skilled in the art will appreciate that the position, velocity, acceleration, etc. of the lower bonding plate mechanism 500 may be computed by the control unit based on one or more position measurements obtained from the output signal of the position sensor 150 and a time base. By way of example, the position sensor may be implemented using a linear voltage differential transformer (LVDT), which provides a varying amplitude output signal as a function of a movable core of the transformer.

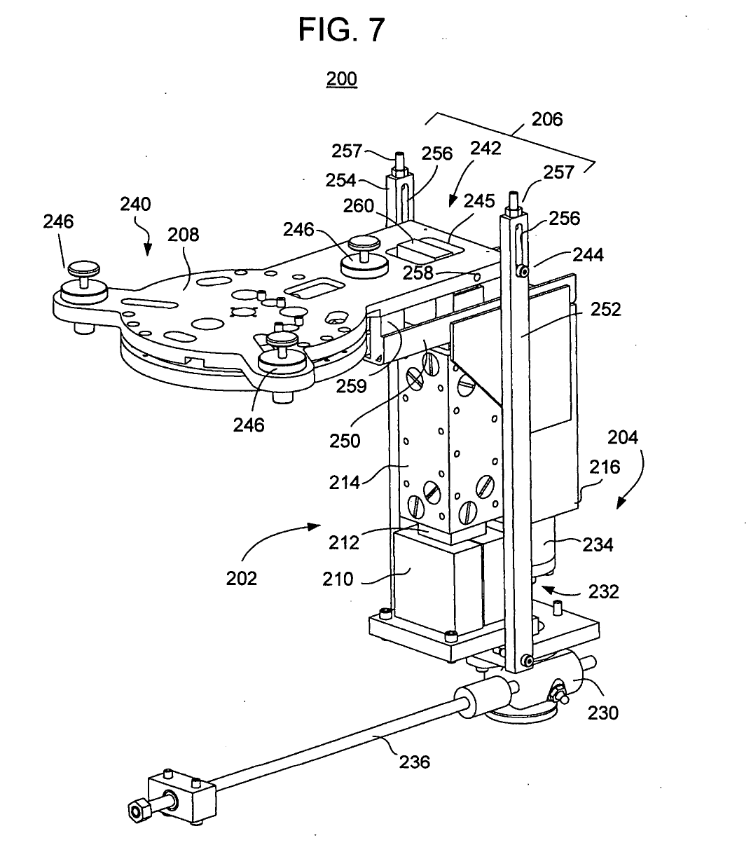

An embodiment of the open and close mechanism 200 will now be discussed with further reference to FIG. 7. In this embodiment, the open and close mechanism 200 includes a lift assembly 202, an actuator assembly 204, a tilt assembly 206, and a mount plate 208. The open and close mechanism 200 is coupled to the upper bonding plate mechanism 400 (not shown in FIG. 7, see FIGS. 1 and 5) and is operable to: (i) assist, when in a closed orientation, in holding the upper bonding plate mechanism 400 in position with respect to the lower bonding plate mechanism 500 such that movement of the lower bonding plate mechanism 500 toward the upper bonding plate mechanism 400 achieves controlled pressure of the silicon donor wafer against the glass substrate; and (ii) provide a dual motion opening profile, where a first motion separates the upper bonding plate mechanism 400 from the lower bonding plate mechanism 500 in a direction substantially perpendicular to the respective bearing planes thereof, and a second motion tilts the upper bonding plate mechanism 400 away from the lower bonding plate mechanism 500 such that the bearing plane of the upper bonding plate mechanism 400 is oblique to the bearing plane of the lower bonding plate mechanism 500.

As to the dual motion opening profile, the lift assembly 202, the actuator assembly 204, the tilt assembly 206, and the mount plate 208 cooperate to achieve two basic movements: (i) a vertical movement of the mount plate 208 with respect to the base plate 12; and (ii) a tilt movement to permit the mount plate 208 to rotate upward with respect to the base plate 12. Noting that the upper bonding plate mechanism 400 is operable to couple to the mount plate 208, the rotation of the mount plate 208 permits access (as discussed above) for inserting the silicon donor wafer and the glass substrate into the bonding apparatus 10 between the upper and lower bonding plate mechanisms 400, 500. The vertical movement of the mount plate 208 (and the upper bonding plate mechanism 400) permits an initial separation motion as between the upper and lower bonding plate mechanisms 400, 500 that is substantially purely vertical. This permits separation without sideways scraping that might otherwise damage the SOG structure. These features will be discussed in more detail below.

The lift assembly 202 includes a base 210, a guide shaft 212, and a guide bushing 214. The base 210 is operable to connect directly or indirectly to the base plate 12 and to provide a rigid reference from which the lift and tilt motions may be launched. The guide shaft 212 is operatively coupled to the base 210 and extends vertically toward the tilt assembly 206 and the mount plate 208. The guide bushing 214 is operable to slidingly engage the guide shaft 212. As will be discussed in more detail below, the sliding movement of the guide bushing 214 with respect to the guide shaft 212 causes the vertical movement and the rotational movement of the mount plate 208. The guide bushing 214 includes a fastening plate 216 that is operable to permit a mechanical linkage to the actuator assembly 204.

The actuator assembly 204 is operable to provide vertical force to the fastening plate 216 of the guide bushing 214, such that controlled sliding of the guide bushing 214 is achieved, again to obtain the lift and tilt motions of the mount plate 208. In one embodiment, the actuator assembly 204 may include a jack 230, such as a Duff-Norton jack, a shaft 232 linked to the jack 230, and a coupling element 234 connected to the fastening plate 216 of the guide bushing 214. In one or more embodiments, the Duff-Norton jack 230 is operable such that application of a rotational force on a shaft 236 causes a vertical movement of the shaft 232 and a resultant vertical movement of the guide bushing 214. The actuation of the jack 230 may be controlled via the control unit, such as by employing an electrical motor to turn the shaft 236.

The mount plate 208 may include a first end 240 that is operable to engage the upper bonding plate mechanism 400, and a second end 242 that is operatively coupled to the tilt assembly 206. In this embodiment, the tilt assembly 206 includes a hinge plate 250 that couples the mount plate 208 to the lift assembly 202 (which will be discussed in more detail below). The tilt assembly 206 also includes first and second stop arms 252, 254 and a pivoting linkage 258 of the hinge plate 250 to the mount plate 208. The stop arms 252, 254 are coupled to the base plate 12 at first ends thereof, and are coupled to the mount plate 208 at second ends thereof. The stop arms 252, 254 may be rotationally coupled to the base plate 12 at the first ends such that vertical movement thereof (with respect to the base plate 12) is prevented but pivotable movement of the second ends about the first ends is permitted. Each of the stop arms 252, 254 include a slot 256 that is operable to receive a corresponding roller or post 244 extending laterally from the second end 242 of the mount plate 208.

The mount plate 208 is operatively coupled to the hinge plate 250 by way of the pivoting linkage 258. More particularly, the hinge plate 250 includes a block 260 that extends at least partially into an aperture 245 of the mount plate 208. The pivoting linkage 258 permits the mount plate 208 to swivel or pivot about the pivoting linkage 258. The aperture 245 may be sized and shaped such that the block 260 may swivel within the aperture 245 without interference.

In response to actuation of the jack 230 (for example, via applying a rotational force to the shaft 236), the shaft 232 may raise/lower the guide bushing 214. In the orientation shown, the guide bushing 214 raises in response to the aforementioned actuation, thereby imparting vertical movement (upward) to the hinge plate 250. In response, the hinge plate 250 applies a vertical force to the mount plate 208 by way of the block 260 and pivoting linkage 258. Notably, the mount plate 208 moves by way of the block 260 in a manner such that the bearing planes of the upper and lower bonding plate mechanisms 400, 500 remain substantially parallel throughout substantially all of a limited travel of the upper bonding plate mechanism 400 during the lift motion.

The vertical force applied to the mount plate 208 by way of the hinge plate 250 causes the rollers or pins 244 of the mount plate 208 to move upward within the respective slots 256 of the respective stop arms 252, 254. The mount plate 208 will, therefore, rise vertically away from the base plate 12 while maintaining a substantially parallel relationship thereto. The vertical upward movement (or lift), while maintaining a substantially parallel orientation with respect to the base plate 12, will continue for limited travel, i.e., until the rollers or pins 244 of the mount plate 208 engage an upper limit within the slots 256. When the rollers or pins 244 reach this limit, a continued upward force on the mount plate 208 by the block 260 causes the first end 240 of the mount plate 208 to tilt upward in response to a rotational movement about the pivoting linkage 258. (Slight pivoting movement of the stop arms 252, 254 about the first ends thereof is permitted to account for lateral movement of the mount plate 208 in response to pivoting about the pivoting linkage 258.) The degree to which the mount plate 208 tilts may be adjusted by way of stops 257 located at the ends of the respective stop arms 252, 254. By way of example, the stops 257 may include threaded rods and nuts, where the threaded rods may be turned into and out of the associated slot 256 by varying amounts. This adjustment in the usable lengths of the slots 256 permit a change in the permissible travel of the rollers or pins 244 and in the degree to which the mount plate 208 tilts.

A reversal of the actuator assembly 204 results in the mount plate 208 tilting downward to its substantially parallel orientation with the base plate 12, followed by a vertical movement downward where the mount plate 208 maintains a substantially parallel relationship with the base plate 12. The parallel orientation of the mount plate 208 may be adjusted by way of one or more stops 259 of the hinge plate 250. For example, the stops 259 may include threaded bolts that may be threaded into and out of the hinge plate 250 to provide an adjustable resting position for the mount plate 208.

The first end 240 of the mount plate 208 also preferably includes a plurality of locks 246 that are operable to engage and couple to upper ends 114A, 116A, 118A of the guide posts 114, 116, 118 of the lift and press mechanism 100 (see FIG. 6). By way of example, the locks 246 may be implemented utilizing threaded bolts that may be manipulated manually. When the mount plate 208 lowers to the position shown in FIGS. 4A, 4B, the locks 246 ensure that the upward pressure on the silicon donor wafer and the upper bonding plate mechanism 400 may be countered by the mount plate 208 without exposing the lift assembly 202, the actuator assembly 204 or the tilt assembly 206 to excessive force.

The first end 240 of the mount plate 208 also includes a plurality of apertures through which various wires, cables, and conduits may pass as will be discussed in more detail hereinbelow.

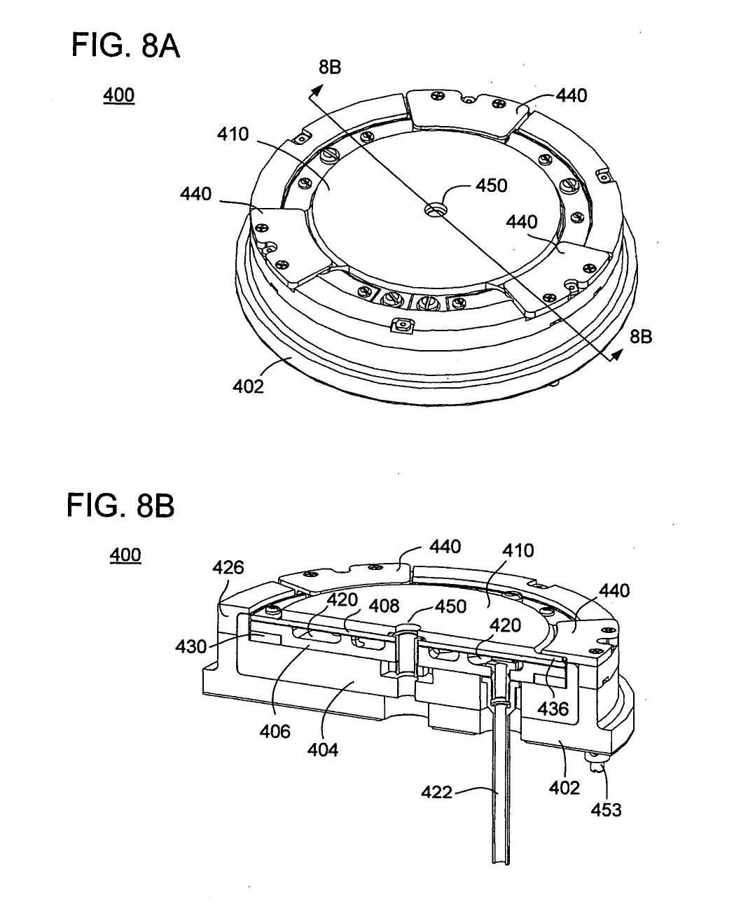

Reference is now made to FIGS. 8A and 8B, which provide further details regarding the upper bonding plate mechanism 400. FIG. 8A is a perspective view of the upper bonding plate mechanism 400, while FIG. 8B is a cross-sectional view thereof. Owing to the symmetry of the bonding apparatus 10, it is noted that the functional and/or structural details of the upper bonding plate mechanism 400 may readily be applied to the lower bonding plate mechanism 500 (as will be discussed below).

The primary components of the upper bonding plate mechanism 400 include a base 402, an insulator 404, a back plate 406, a heater disk 408, and a thermal spreader 410. The primary functions of the upper bonding plate mechanism 400 include heating the silicon donor wafer, providing pressure to the silicon donor wafer, providing a voltage potential to the silicon donor wafer, and cooling the silicon donor wafer.

The heating function originates at the heater disk 408 and is operable to provide temperatures lower or greater than about 600° C., and may approach or exceed temperatures of 1,000° C. This embodiment of the upper bonding plate mechanism 400 is also operable to provide the heat uniformly to within ±0.5% of the controlled set-point across substantially the entire silicon donor wafer.

The pressure imparted to the silicon donor wafer by the upper bonding plate mechanism 400 is substantially uniformly distributed over the wafer by way of the thermal spreader 410, which provides a counter-force to the upward pressure by the glass substrate (imparted by the lower bonding plate mechanism 500). This results in a pressure profile at the interface of the silicon donor wafer and the glass substrate suitable for anodic bonding. By controlling the upward pressure imparted by the lower bonding plate mechanism 500 (e.g., under the control of the control unit) the pressure profile may include at least a peak pressure of between about 1 pound per square inch (psi) to 100 psi. Lower pressures of between about 10 to 50 psi (for example, about 20 psi) are believed advantageous as they are less likely to crack the silicon donor wafer or the glass substrate.

As discussed above, the silicon donor wafer and the glass substrate are subject to a differential voltage potential of about 1750 volts DC, which is imposed by the respective upper and lower bonding plate mechanisms 400, 500. It is noted that this voltage potential may be achieved by: (i) applying a voltage potential to one of the silicon donor wafer and the glass substrate (while grounding the other); or by (ii) applying respective voltage potentials to both the silicon donor wafer and the glass substrate (such as a positive voltage potential to the silicon donor wafer and a negative voltage potential to the glass substrate). Thus, the ability of the upper bonding plate mechanisms 400 to impart a voltage potential (other than ground) to the silicon donor wafer is an optional feature. If a bonding voltage potential (other than ground) is applied to the silicon donor wafer by the upper bonding plate mechanism 400, such may be distributed by the thermal spreader 410 substantially uniformly over the entire surface of the wafer.

While the present invention is not limited by any theory of operation, it is noted that there may be a general relationship between bonding voltage, temperature, time, and material properties. For example, as the bonding voltage decreases, the temperature, time and/or amount of conductivity ions (e.g., of the glass substrate) may be increased to at least tend toward the same bonding result. The relationship also holds when the temperature, time and/or amount of conductivity ions are the independent variable. The bonding voltage potential between the silicon donor wafer and the glass substrate may be in the range of about 100 volts DC (or lower) to about 2000 volts DC (or greater) and may be measured using peak, average, RMS, or other measurement conventions. For certain type of glass substrates a bonding voltage in the range of about 1000 volts DC to about 2000 volts DC is suitable.

If active cooling of the silicon donor wafer is desired, such may be achieved utilizing controlled fluid flow through the upper bonding plate mechanism 400. These and other features of the upper bonding plate mechanism 400 will be discussed in more detail below.

The base 402 of the upper bonding plate mechanism 400 is of substantially cylindrical construction and defines an interior volume for receiving the insulator 404. By way of example, the base 402 may be formed from a machinable glass ceramic (e.g., MACOR), which provides structural integrity as well as high temperature capabilities. Other suitable materials may additionally or alternatively be employed to form the base 402. The insulator 404 is operable to limit or impede heat flow from the heater disk 408 into the base 402 (and other portions of the bonding apparatus 10). By way of example, the insulator 404 may be formed from a ceramic foam insulating material, such as 40% dense fused silica. Other suitable insulating materials may additionally or alternatively be employed. The insulator 404 should provide significant insulating capabilities inasmuch as the heater disk 408 is operable to attain temperatures of 600° C. or more, such as reaching or exceeding 1,000° C. It is noted that insufficient insulation that would permit significant heat flow into the base 402 could have catastrophic consequences in terms of the proper operation of other portions of the bonding apparatus 10. In addition, a relatively high degree of insulation as between the base 402 and the heater disk 408 insures a relatively low thermal inertia of the upper bonding plate mechanism 400, which assists in achieving rapid thermal cycling capabilities.

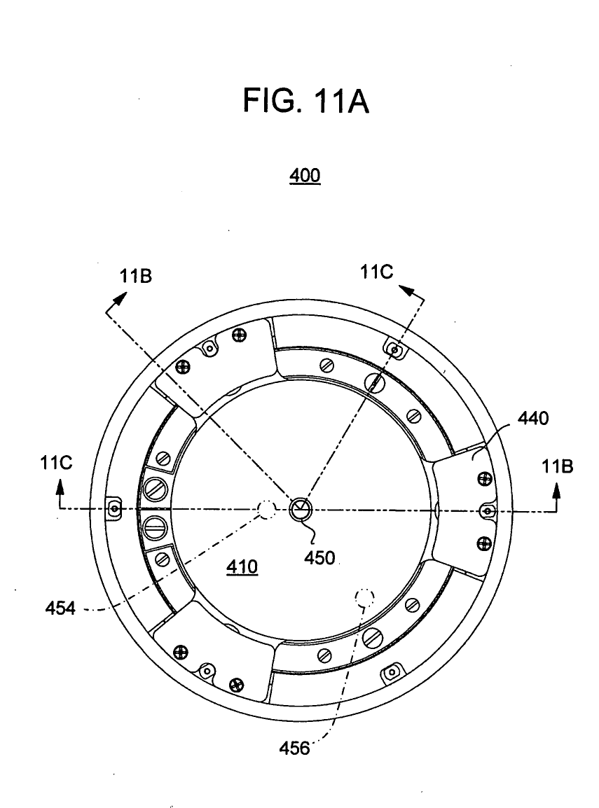

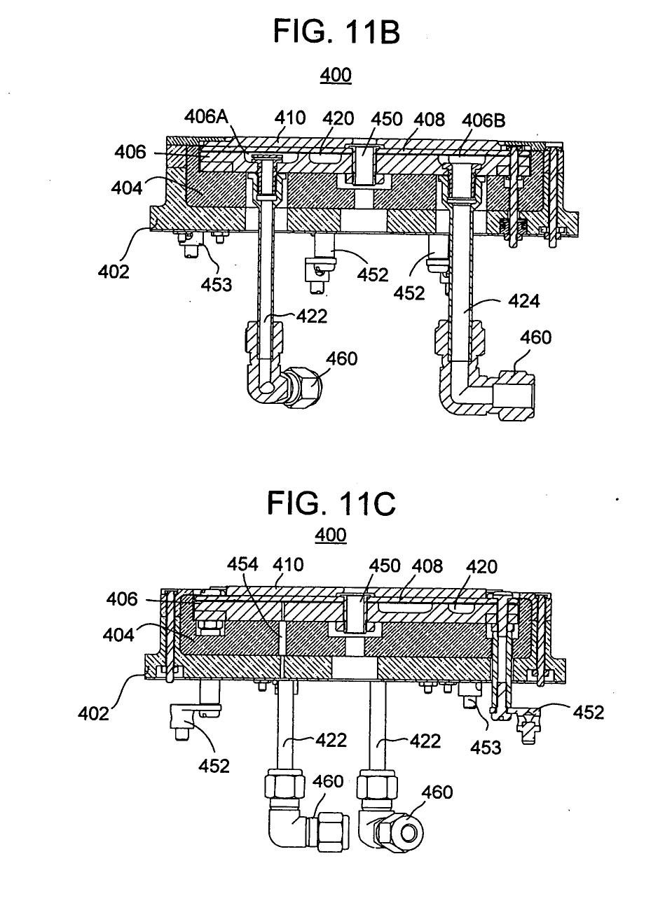

The back plate 406 is insulated from the base 402 by way of the insulator 404. The back plate 406 is operable to provide at least one cooling channel 420 through which cooling fluid may flow when it is desirable to actively reduce the temperature of the SOG structure, specifically the silicon donor wafer. By way of example, the back plate 406 may be formed from hot pressed boron nitride (HBN) in order to withstand high temperatures and relatively rapid changes in temperature (as is the case when cooling fluid is introduced into the channel 420). Other suitable materials may additionally or alternatively by employed to form the back plate 406. At least one inlet tube 422 is operable to introduce cooling fluid into the channel 420, while at least one outlet tube 424 (not viewable in FIG. 8B, but see FIG. 11B, as will be discussed below) is operable to remove the cooling fluid from the channel 420. A heat exchanger (not shown) may be employed to cool the cooling fluid prior to reintroducing same into the inlet tube 422.

Active cooling may be achieved by controlling the temperature and flow rate of the cooling fluid through the channel 420 using the control unit. For example, the cooling profile of the upper bonding plate mechanism 400 may be actively controlled (e.g., by the control unit) to provide at least one of differing rates of cooling and differing levels of cooling (e.g., dwells) to the silicon donor wafer. It is believed that providing differing cooling profiles to the silicon donor wafer and the glass substrate, respectively, facilitates better separation of the exfoliation layer from the silicon donor wafer. Notably, the active cooling feature of the upper bonding plate mechanism 400 is optional as the differential cooling profiles as between the silicon donor wafer and the glass substrate, respectively, may be achieved through active cooling of the glass substrate (and not the silicon donor wafer) via the lower bonding plate mechanism 500 (as will be discussed in more detail below).

A cap ring 426 (see FIG. 8B) is operable to maintain the insulator 404 in position within the base 402 as well as to provide a recess within which the heater disk 408 may be disposed. The cap ring 426 may be formed from a machinable glass ceramic (such as the aforementioned MACOR).

The heater disk 408 is operable to generate heat in response to electrical excitation (voltage and current), while also providing electrical insulation properties such that the potential applied to the silicon donor wafer is not applied to the back plate 406 or the base 402. Indeed, the relatively high voltage potential applied to the silicon donor wafer should be confined. Thus, the heater disk 408 may be formed from a material that exhibits substantial electrical insulting properties and substantial thermal conductivity. One such suitable material is pyrolytic boron nitride (PBN).

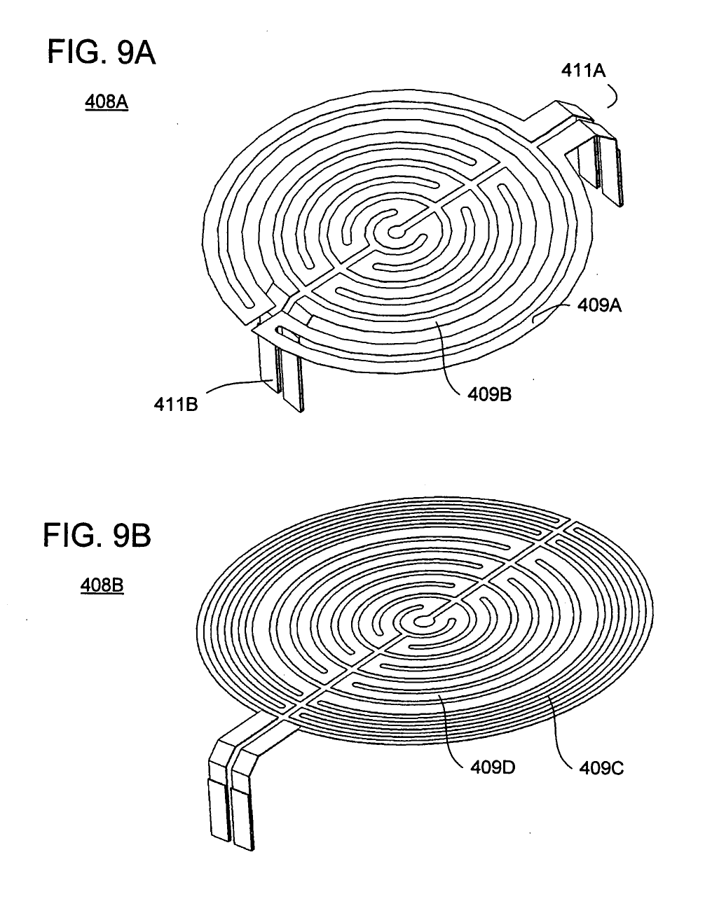

With reference to FIGS. 9A and 9B, two examples of heater disk designs are illustrated that are suitable for implementing the heater disk 408. FIG. 9A is a perspective view of a first heater disk 408A, while FIG. 9B is a perspective view of an alternative, second heater disk 408B. As substantially uniform heating is desired, the heater disks 408A, 408B may include thermal edge loss compensation, such that the tendency for outer portions of the heater disks 408A, 408B to run cooler than the central portions thereof may be managed. In the embodiments shown, the thermal edge loss compensation of the heater disks 408A, 408B may be achieved using two heating zones, one substantially centrally located and the other in the form of an annular ring around the central zone. The heating zones may be implemented using respective heating elements.

The heater disk 408A of FIG. 9A includes two separate heating elements 409A and 409B, where heating element 409B is substantially centrally located and heating element 409A is in the form of an annular ring around heating element 409B. Each heating element 409A, 409B includes a pair of terminals 411A, 411B to which respective power sources may be connected. The voltage and current excitation from the respective power sources to the heater elements 409A and 409B of the heater disk 408A may be separately controlled via the control unit such that the respective temperatures of the two heating zones may be separately regulated and compensation of thermal edge loss may be achieved.

The heating elements 409A and 409B may be formed from pyrolytic graphite (PG), THERMAFOIL, etc. THERMOFOIL material is a thin, flexible material having heating properties, which include an etched foil resistive element laminated between layers of flexible insulation. While THERMOFOIL may exhibit better reliability in a vacuum environment, non-vacuum environments (which may include one or more oxidizing agents, such as air environments) are also contemplated herein. In a non-vacuum atmosphere, the heating elements 409A and 409B may be formed from INCONEL, which includes a family of high strength austenitic nickel-chromium-iron alloys that have good anti-corrosion and heat-resistance properties.

In one or more embodiments, the heater elements 409A and 409B may be vertically offset to assist in thermal edge loss compensation. For example, the heater element 409B in the central zone may be located toward a bottom side of the heater disk 408A, while the heater element 409A in the annular zone may be disposed at or toward the upper side of the heater disk 408A. This reduces the thermal resistance between the heater element 409A at the periphery of the heater disk 408A and the silicon donor wafer as compared with the thermal resistance between the heater element 409B at the center of the heater disk 408A and the silicon donor wafer. The offset feature may be achieved, for example, by interposing a spacer element (not shown), e.g., a sheet of material, between the heater elements 409A, 409B. This may also permit the terminals 411B to exit laterally rather than downward as illustrated in FIG. 9A.

The heater disk 408B of FIG. 9B includes an integrally formed, contiguous heating element that operates as if having separate heating elements 409C, 409D. In particular, the widths (and/or the thickness) of the resistive material used to form the heating element is varied depending on its location within the heater disk 408B. For example, the width of the heating element at peripheral positions 409C is lower than the width of the heating element at central positions 409D. Varying the width of the heating element changes the resistance of (and thus the heating characteristics) of the heating element as a function of position. By varying the resistance of the integrated heating element as a function of position from a central region of the heater disk 408B, only a single voltage and current excitation is needed to achieve the thermal edge loss compensation. Indeed, the integrated heater element will respond (heat) differently in response to the excitation voltage and current due to the varying resistance of same in regions 409C and 409D.

Irrespective of the heater element construction, the resistance of the heating element(s) may be on the order of about 10-20 Ohms (e.g., about 15 Ohms). To achieve the aforementioned heating levels of about 600° C. to 1000° C., a voltage of about 220 volts (AC) may be applied across the heating elements, which causes a heat dissipation on the order of about 3250 Watts RMS.

In one or more embodiments, the heater disk 408 exhibits relatively low thermal inertia, due at least in part by the choice of materials and construction. The heater disk may measure about 2 mm thick using the materials and construction details discussed above. The relatively low thickness (as compared with prior art heating elements measuring 1-2 inches thick) contributes to a lower thermal mass and thermal inertia, which assists in achieving rapid thermal cycling capabilities.

The thermal spreader 410 is in thermal communication with the heater disk 408 and is operable to integrate the heating profile presented by the heater disk 408 such that a more uniform presentation of heat is imparted to the silicon donor wafer. The thermal spreader 410 may be both electrically and thermally conductive, as it is in direct contact with the silicon donor wafer and facilitates heating the wafer and applying the aforementioned high voltage thereto.

Among the materials that may be employed to implement the thermal spreader 410, electrically conductive graphite is desirable, such as THERMAFOIL. In a non-vacuum atmosphere (e.g., air), the thermal spreader 410 may be formed from other materials that may exhibit better reliability in oxidizing environments, such as a non-oxidizing electro-thermal conductive element, copper with a non-oxidizing coating (such as electroless nickel, platinum, molybdenum, tantalum, etc.), THERMOFOIL with a non-oxidizing coating (such as electroless nickel, platinum, molybdenum, tantalum, etc.), silicon carbide (which may or may not be coated) KEVLAR with a metal coating (such as electroless nickel, platinum, molybdenum, tantalum, etc.).

In one or more embodiments, the thermal spreader 410 also exhibits relatively low thermal inertia, due again at least in part by the choice of materials and construction. The thermal spreader 410 may measure about 0.5-6 mm thick using the materials and construction details discussed above.

The relatively low thicknesses of the heater disk 408 and the thermal spreader 410, coupled with the high insulation properties exhibited by the insulator 404 and other material choices discussed above, contribute to very low thermal mass and thermal inertia of the upper bonding plate mechanism 400. Thus, the upper bonding plate mechanism 400 may heat a material sheet from room temperature to about 1000° C. in about 2 minutes and cool same to room temperature in about 10 minutes or less. This is in comparison to prior art substrate heaters, which may take about one-half hour to one hour to elevate a material sheet from room temperature to only about 600° C., and may take about 20 minutes to cool the material sheet to room temperature.

The control unit is operable to program the upper bonding plate mechanism 400 to follow any desired heat-up or cool down ramp and dwell at any desired processing temperature.

As shown in FIG. 8A, the upper bonding plate mechanism 400 may include an aperture 450 that permits access to the silicon donor wafer during the bonding process, for example to impart a pre-charge voltage to the wafer. This optional feature will be discussed in further detail later in this description.

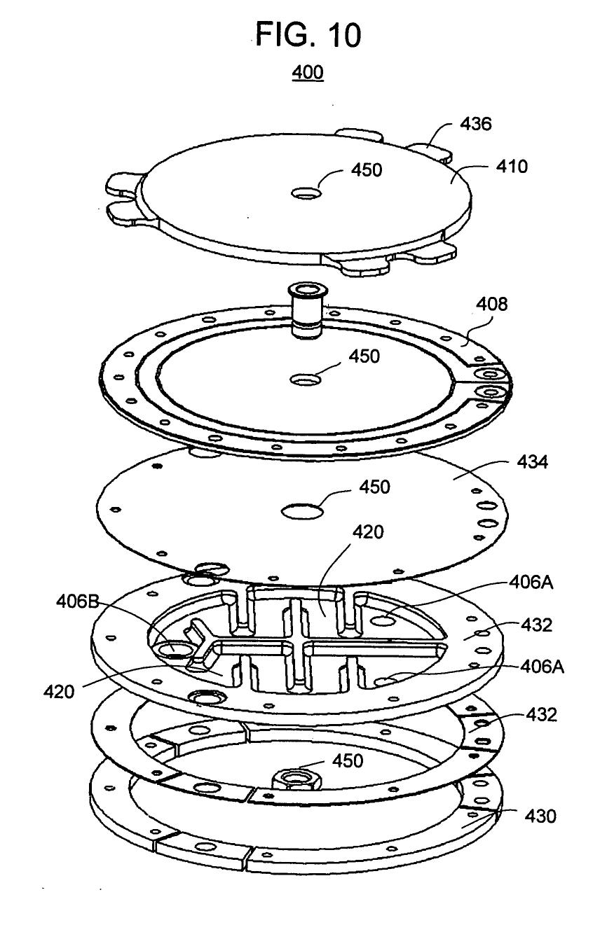

FIG. 10 illustrates an exploded view of the upper bonding plate mechanism 400 (excluding the base 402 and the insulator 404). As shown in the exploded view, the upper bonding plate mechanism 400 is a multi-layer assembly including a support ring 430, a gasket 432, the back plate 406, a gasket 434, the heater disk 408, and the thermal spreader 410. The support ring 430 provides a support for the back plate 406 and for the gasket 432. The back plate 406 is sandwiched between the gasket 432 and the gasket 434, which operate to prevent the cooling fluid from leaking as it flows through the channels 420. Among the materials from which the gaskets 432, 434 may be formed, the GRAFOIL ring material is desirable because it exhibits suitable sealing and heat resistant properties. The heater disk 408 overlies the gasket 434 and the thermal spreader 410 is disposed above the heater disk 408. The respective layers of the upper bonding plate mechanism 400 may be coupled to one another utilizing bolts.

In one or more embodiments, the back plate 406 may include a single, contiguous channel 420 or multiple separate channels 420. As illustrated in FIG. 10, the back plate 406 includes two separate channels 420, which each receive cooling fluid via respective inlets 406A, 406B, and emit the cooling fluid via a shared outlet 406C. The dual cooling channels 420 ensure more even cooling across the thermal spreader 410 (and thus the silicon donor wafer).

Notably, the thermal spreader 410 includes a plurality of fins 436 that extend radially outward from a peripheral edge of the thermal spreader 410. The fins 436 provide a peripheral surface that is utilized to maintain the thermal spreader 410 in position and to provide a connection to a high voltage source. As best seen in FIG. 8B, the fins 436 are engaged by respective retainer clips 440 and prevent the thermal spreader 410 from moving. Preferably, the retainer clips 440 are formed from a machinable glass ceramic (e.g., MACOR), such that they provide electrical insulation and good structural integrity.

As discussed above, the upper bonding plate mechanism 400 may optionally include the aperture 450, which may be implemented by way of separate apertures 450 of the base 402, the insulator 404, the back plate 406, the heating disk 408, and the thermal spreader 410. The aperture 450 may be centrally located such that access to a central region of the silicon donor wafer (e.g., the center thereof) may be obtained. A use of the access to the silicon donor wafer provided by the aperture 450 will be discussed in more detail below.

Reference is now made to FIGS. 11A, 11B, and 11C, which illustrates further structural and functional aspects of the upper bonding plate mechanism 400. FIGS. 11B and 11C are cross-sectional views taken through lines 11B-11B and 11C-11C, respectively. As best seen in FIG. 11C, excitation voltage and current may be applied to the heater disk 408 by way of terminals 452, which extend through the base 402, the insulator 404, and the back plate 406. The number of terminals 452 will depend on how many heating elements are employed in the heating disk 408 and how the heating elements are implemented. As discussed above, in one or more embodiments, two heating elements may be employed for which the excitation voltages and current may be separately controlled via the control unit such that the temperatures of the two heating zones may be tightly regulated. Alternatively, the heating elements may be integrated (using variable resistance) such that a single excitation voltage may be employed for temperature regulation and edge loss compensation.

As best seen in FIG. 11B, respective fluid couplings 460 may be connected to the inlet tube(s) 422 and the outlet tube 424 to permit the connection of a fluid source (not shown) to the upper bonding plate mechanism 400. Notably, the inlet tube 422 and outlet tube 424 extend far enough from the base 402 to pass through apertures in the mount plate 208.

As best seen in FIGS. 11B and 11C, a relatively high voltage potential (e.g., as compared to the heater voltage) may be applied to the thermal spreader 410 by way of high voltage terminal 453, which extends through the base 402, the insulator 404, the back plate 406, and the heater disk 408. As discussed above, the voltage applied to the thermal spreader 410 (which may be between about 1000 to 2000 volts DC) is employed to assist in the anodic bonding of the silicon donor wafer to the glass substrate.

Although not shown, the upper bonding plate mechanism 400 may also include one or more vacuum conduits that extend to the thermal spreader 410, through the base 402, the insulator 404, the back plate 406, and the heater disk 408. If employed, the vacuum conduits permit the application of a vacuum to the silicon donor wafer when it is placed against the thermal spreader 410 such that the wafer will be coupled to the thermal spreader 410 when the upper bonding plate mechanism 400 is in the upwardly rotated (open) position, as shown in FIG. 2. Application of the vacuum may be achieve using a conventional vacuum source (not shown) that is controlled via the control unit or manually by an operator of the bonding apparatus 10.

As discussed above, the upper bonding plate mechanism 400 may optionally include the aperture 450 to permit access to the silicon donor wafer during the bonding process. When the aperture 450 is employed, a preferred use thereof is to permit a preload pressure and/or seed voltage to be applied to the silicon donor wafer prior to application of the bonding voltage. The purpose of the preload pressure and seed voltage is to initiate anodic bonding in a localized area of the interface between the silicon donor wafer and the glass substrate prior to application of the bonding voltage, which facilitates anodic bonding across substantially the entire area of the interface. The seed voltage may be of the same or different magnitude as the bonding voltage, however, a lower or equal voltage is believed to be superior, e.g., about 750-1000 volts DC. The aperture 450 may be centrally located such that the initial anodic bonding occurs at or near a central region of the interface between the silicon donor wafer and the glass substrate.

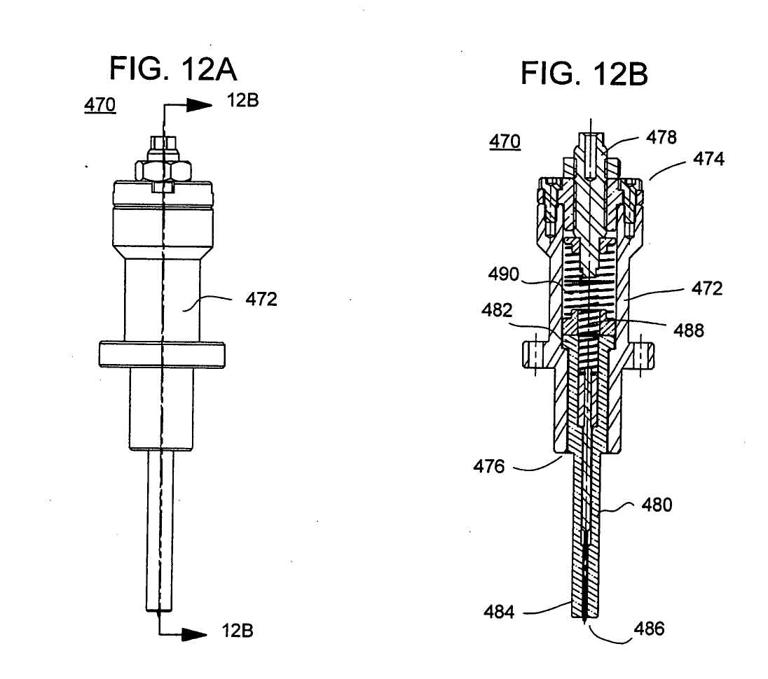

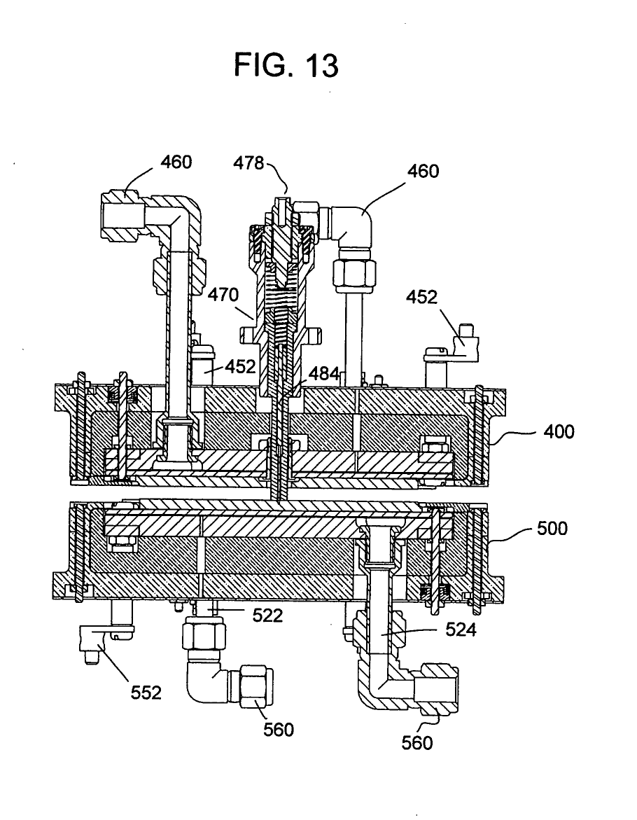

Reference is now made to FIGS. 12A, 12B, and 13, which illustrate a suitable apparatus for achieving aforementioned preload pressure and seed voltage functionality. FIG. 12A illustrates a side view of a preload plunger 470 that is operable to engage the upper bonding plate mechanism 400 and extend through the aperture 450 thereof to mechanically and electrically communicate with the silicon donor wafer. FIG. 12B is a cross-sectional view of the preload plunger 470 of FIG. 12A, while FIG. 13 is a cross-sectional view of the upper and lower bonding plate mechanisms 400, 500 with the preload plunger 470 coupled to the upper bonding plate mechanism 400. The preload plunger 470 includes a housing 472 having a proximal end 474 and a distal end 476. An electrical terminal 478 is disposed at the proximal end of the housing 474 and provides a means for connecting a voltage source from which the preload potential is obtained. A plunger 480 is partially disposed within the housing 472 and extends through the distal end 476 of the housing 472. The plunger 480 is slideable within the housing 472, in a telescoping fashion. The plunger 480 includes a stop 482 at one end to prevent the plunger 480 from passing all the way through the distal end 476 and becoming disengaged from the housing 472. An electrode 484 is coaxially disposed within the plunger 480, where a tip 486 of the electrode 484 extends beyond an end of the plunger 480. (As will be discussed in more detail below, the tip 486 engages the silicon donor wafer.)

A first compression spring 488 mechanically and electrically couples the electrode 484 and the terminal 478 such that the slideable movement of the plunger 480 does not disturb the electrical connection between the terminal 478 and the electrode 484. The first compression spring 488 also urges or biases the electrode 484 (and the plunger 480) forward such that the stop 482 engages the housing 472. A second compression spring 490 also urges the plunger 480 forward such that the stop 482 engages the housing 472 and biases the plunger 480 and the electrode 484 in an extended orientation. An axially directed force on the electrode 484 and the plunger 480 is absorbed by the respective compression springs 488, 490 such that the tip 486 of the electrode 484 is biased toward and maintains an electrical connection with the silicon donor wafer. The electrode 484 thus delivers the seed voltage to the silicon donor wafer. In one or more embodiments, the electrode 484 may slide within the plunger 480, such that the plunger 480, itself, is also biased toward and applies (alone or in combination with the electrode 484) the preload pressure on the silicon donor wafer.

In a preferred embodiment, the tip 486 of the electrode 484 extends below the thermal spreader 410 of the upper bonding plate mechanism 400 such that it contacts the silicon donor wafer when the lift and press 100 mechanism coarsely displaces the lower bonding plate mechanism 500 toward the upper bonding plate mechanism 400 (i.e., as shown in FIGS. 4A-4B before the bonding apparatus 10 is fully closed). Thus, application of the preload pressure and seed voltage may initiate the anodic bonding of the silicon donor wafer and the glass substrate before full pressure, temperature, and voltage is applied.

Similar to the application of the bonding voltage to the silicon donor wafer and the glass substrate, the seed voltage potential may be achieved by: (i) applying a voltage potential to one of the silicon donor wafer and the glass substrate (while grounding the other); or by (ii) applying respective voltage potentials to both the silicon donor wafer and the glass substrate. Thus, even if initial bonding in a localized area of the interface between the silicon donor wafer and the glass substrate is desired, the ability of the upper bonding plate mechanisms 400 to impart the seed voltage potential to the silicon donor wafer is an optional feature. Indeed, as will be discussed later in this description, the seed voltage potential may be applied to the glass substrate by way of the lower bonding plate mechanism 500 (while grounding the silicon donor wafer).

While the preload pressure and seed voltage may be applied as discussed above, it is desirable to limit the contact area of the silicon donor wafer and the glass substrate while the preload pressure and seed voltage are applied in order to limit the area over which pre-bonding is permitted. In this regard, the spacer mechanism 300 may be used in combination with the aforementioned preload plunger 470. In general, the spacer mechanism 300 is coupled to the lower bonding plate mechanism 500 (see FIGS. 1 and 5) and is operable to prevent peripheral edges of the silicon donor wafer and the glass substrate from touching one another when pre-bonding is achieved in the central region thereof. After the pre-bonding is achieved, the spacer mechanism 300 permits the silicon donor wafer and the glass substrate to touch one another (including the peripheral edges thereof) for the fall bonding procedure to be carried out.

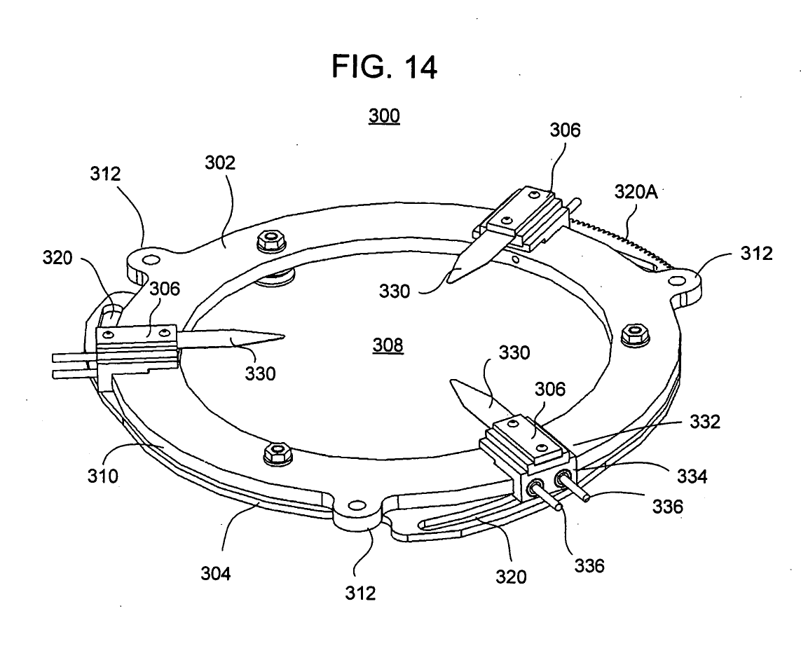

Reference is now made to FIG. 14, which is a perspective view of the spacer mechanism 300. The spacer mechanism 300 is operable to mechanically assist in holding the peripheral regions of the silicon donor wafer and the glass substrate away from one another during the application of the preload pressure and seed voltage. In one or more embodiments, the spacer mechanism 300 is operable to provide symmetrical (multi-position) shim action as between the silicon donor wafer and the glass substrate.

The spacer mechanism 300 is of substantially annular construction and includes a mount ring 302, a swivel ring 304, and a plurality of shim assemblies 306. The mount ring 302 is of substantially annular construction including a central aperture 308 and a peripheral edge 310. A plurality of mounting elements (such as apertures) 312 are disposed about the peripheral edge 310 and are of complementary construction as the mounting elements 140, which may be upwardly directed posts 140 (see FIGS. 1, 5, and 6). The size, shape and positions of the mounting elements 140 and 312 are such that the mount ring 302 may be coupled to the lower mount 108 of the lift and press mechanism 100. In the illustrated embodiment, the mount ring 302 cannot rotate with respect to the lower mount 108 of the lift and press mechanism 100.

The swivel ring 304 is also of substantially annular construction and further defines the central aperture 308. The swivel ring 304 is rotationally coupled to the mount ring 302 and, therefore, may rotate with respect to the mount ring 302 and the lower mount 108 of the lift and press mechanism 100. The swivel ring 304 includes a plurality of cams 320 (e.g., cam slots) disposed at a peripheral edge thereof, which may include one such cam 320 for each of the shim assemblies 306. One of the cams 320A is a geared cam, including a plurality of teeth that are of a pitch that corresponds with a gear 142 of a stepper motor 144 of the lift and press mechanism 100 (see FIG. 6). As the stepper motor 144 turns the gear 142, the swivel ring 304 rotates with respect to the mount ring 302 and the lower mount 108 of the lift and press mechanism 100. The control unit may provide drive excitation to the stepper motor 144 to obtain precise rotational movement of the swivel ring 304.

Each shim assembly 306 may include a shim 330 coupled to a slide block 332. The shim 330 is sized and shaped to fit between, and separate, the silicon donor wafer and the glass substrate. The shim is operable to achieve radial inward and outward movement with respect to a center area of the spacer mechanism 300 (and thus a central area of the interface between the silicon donor wafer and the glass substrate). This radial movement is achieved by way of slideable engagement between the slide block 332 and the mount ring 302. For example, each shim assembly may include one or more guide bushings 334 that slidingly engage a corresponding one or more pins 336. The pins 336 may extend radially away from the peripheral edge 310 of the mount ring 302 such that sliding movement of the guide bushings 334 along the pins 336 results in the aforementioned radial movement of the slide block 332 and the shim 330.

Each slide block 332 also includes a cam guide (not visible), such as a roller or post, that engages the respective cam slot 320. Rotation of the swivel ring 304 (via actuation of the stepper motor 144) applies radial forces to the respective slide blocks 332 such that they slide in a controlled fashion along the posts 336 (via the guide bushings 334). Thus, all the shims 330 move in symmetric motion, which prevents any uneven frictional loads as between the silicon donor wafer and the glass substrate. It is noted that the rotation of the swivel ring 304 may be achieved using other actuation means, such as a pneumatic cylinder, linear motor, solenoid arrangement, etc. The shims 330 are preferably electrically insulated such that the voltage potential(s) of the SOG are not permitted to couple to the mount ring 302 and other portions of the bonding apparatus 10. For example, the slide blocks 332 may be formed with ceramic material. The mount ring 302 and swivel ring 304 may be positioned below the high heat zone of the lower bonding plate mechanism 500, which protects them from excessive heat input.

As best seen in FIG. 11A, the upper bonding plate mechanism 400 may include one or more further apertures to permit access to the heater disk 408. By way of example, a first aperture 454 may permit the insertion of a thermocouple through the assembly such that it may thermally engage the heater disk 408 and provide a temperature feedback signal to the control unit (which permits tight temperature regulation of the heater disk 408 and the silicon donor wafer). It is noted that the aperture 454 extends from the rear of the upper bonding plate mechanism as viewed in FIG. 11A and is thus shown in dashed line. A second aperture 456 (also from the rear) may also be included that provides additional access to the heater disk 408 for further thermal regulation. Notably, the first aperture 454 is disposed in the area of the central heating element of the heater disk 408, while the second aperture 456 is disposed at or near the annular heating element of the heater disk 408. This permits independent feedback and control of the energizing signals to the respective central and annular heating elements (unless they are integrally formed), thereby permitting compensation for thermal edge effects as well as overall temperature regulation.

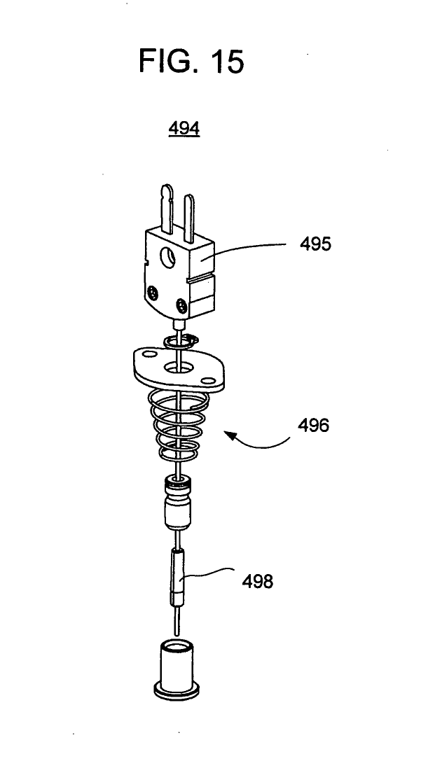

FIG. 15 is a perspective view of a thermocouple assembly 494 that may be employed to extend through the apertures 454, 456 and engage the heater disk 408. The thermocouple assembly 494 includes a standard thermocouple plug 495, a spring assembly 496, and a probe 498. The probe 498 is operatively urged forward by the spring assembly 496 such that it is biased against the heater disk 408, thereby insuring suitable thermal conductivity therebetween.

The structural details of one or more embodiments of the lower bonding plate mechanism 500 will now be described. The primary functions of the lower bonding plate mechanism 500 are complimentary to those of the upper bonding plate mechanism 400, namely, heating the glass substrate, providing pressure to the glass substrate, providing a voltage potential to the glass substrate, and cooling the glass substrate.

In accordance with one or more embodiments, the lower bonding plate mechanism 500 may include any number of the features of the embodiments of the upper bonding plate mechanism 400 described above. For example, in the embodiment illustrated in FIG. 13, the upper and lower bonding plate mechanisms 400, 500 are substantially the same, except the upper bonding plate mechanism 400 employs the aperture 450 and pre-load plunger 470, while the lower bonding plate mechanism 500 does not.

The heating function of the lower bonding plate mechanism 500 is operable to provide temperatures lower or greater than about 600° C., which may approach or exceed temperatures of 1,000° C. The lower bonding plate mechanism 500 may be operable to provide heat uniformly to within ±0.5% of the controlled set-point across substantially the entire glass substrate. The voltage potential (about 1,750 volts DC) may optionally be applied to the glass substrate by the lower bonding plate mechanism 500, and may be distributed substantially uniformly over the entire surface of the substrate. Alternative embodiments of the lower bonding plate mechanism 500 may provide for active cooling of the glass substrate utilizing controlled fluid flow.

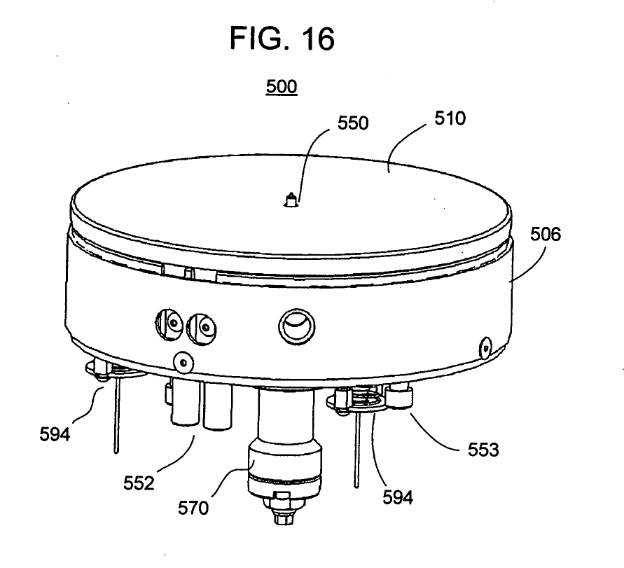

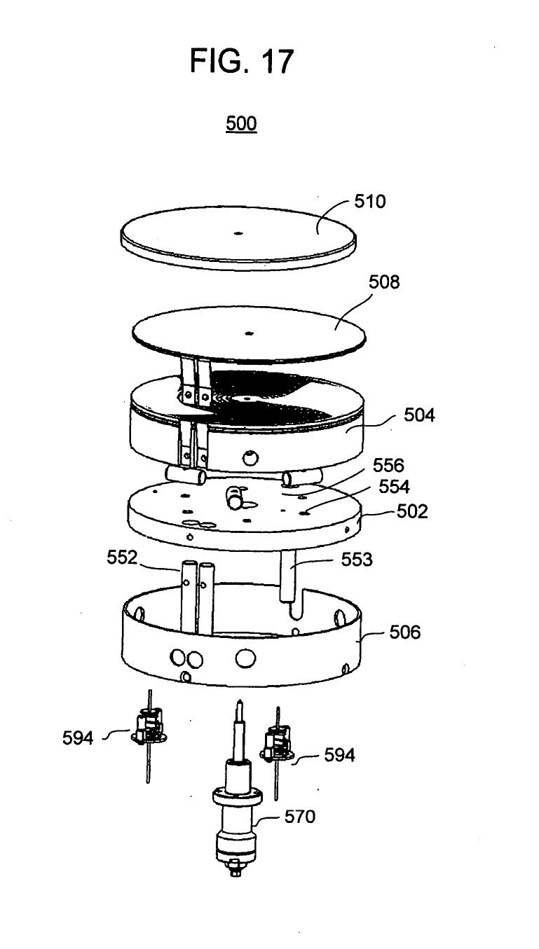

While the embodiment of the lower bonding plate mechanism 500 illustrated in FIGS. 16-21 contains similar features as the upper bonding plate mechanism 400 discussed above, the lower bonding plate mechanism 500 may also include some different features. FIG. 16 is a perspective view of the lower bonding plate mechanism 500, while FIG. 17 is an exploded view thereof. The primary components of the lower bonding plate mechanism 500 include a base 502, an insulator 504, a heater disk 508, and a thermal spreader 510. These elements are disposed within, coupled to, or supported by a housing 506, which may be formed for example from stainless steel.

The base 502 is coupled to a lower portion of the housing 506, thereby forming a substantially cylindrical structure defining an interior volume for receiving the insulator 504. By way of example, but not limitation, the base 502 may be formed from a machinable ceramic material (e.g., Cotronics 902 machinable alumina silicate), which provides structural integrity as well as high temperature capabilities. The insulator 504 is operable to limit heat flow from the heater disk 508 into the base 502, housing 506 and other portions of the bonding apparatus 10. By way of example, but not limitation, the insulator 504 may be formed from a ceramic foam insulating material, such as 40% dense fused silica. The temperature insulating properties of the insulator 504 should prevent heat flow from the heater disk 508 into the base 502 (and other components) and provide a relatively low thermal inertia of the lower bonding plate mechanism 500 (for rapid thermal cycling capabilities).

The heater disk 508 and the insulator 504 may be bonded together using a ceramic adhesive, such as Cotronics RESBOND 905.

The heater disk 508 is operable to generate heat in response to electrical excitation (voltage and current), while also providing electrical insulation properties such that any voltage potential directly or indirectly applied to the glass substrate is not applied to the base 502 or housing. Thus, the heater disk 508 may be formed from a material that exhibits substantial electrical insulting properties and substantial thermal conductivity.

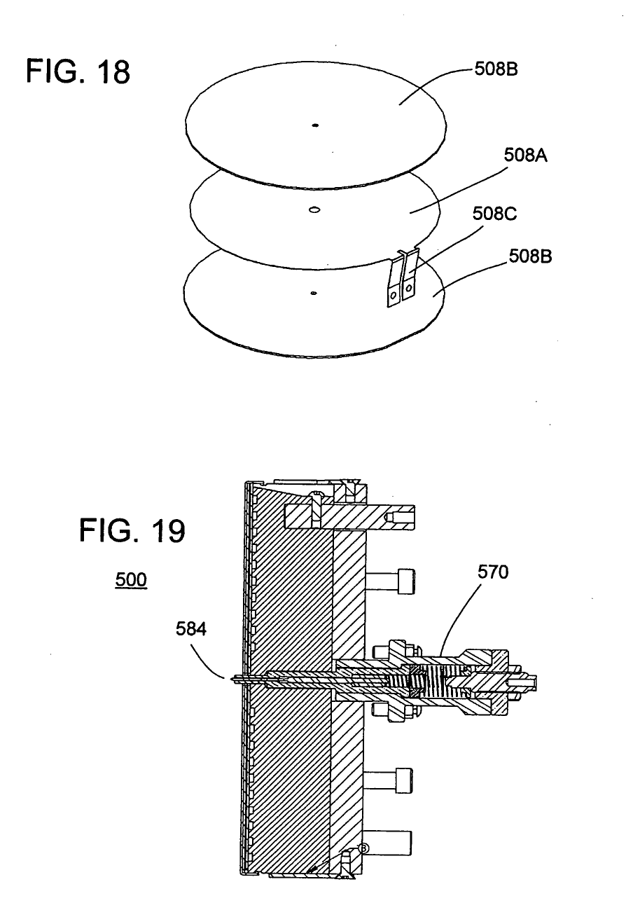

With reference to FIG. 18, the heater disk 508 may be formed from a resistive heater layer 508A sandwiched between two (or more) electrical insulating layers 508B. By way of example, and not limitation, the resistive heater layer 508A may be formed from THERMAFOIL rolled graphite and the electrical insulating layers 508B may be formed from fused silica. The resistive heater layer 508A and the electrical insulating layers 508B may be bonded together using a ceramic adhesive, such as Cotronics RESBOND 905 (which exhibits low thermal expansion characteristics).

As substantially uniform heating is desired, the heater disk 508 may include thermal edge loss compensation. In this embodiment, the heater disk 508 may include two heating zones, one substantially centrally located and the other in the form of an annular ring around the central zone. The heating zones may be implemented within the resistive heater layer 508A. For example, the respective heating zones may be formed by varying respective widths of resistive material as the material spirals outward from a center of the layer 508A. This results in a varying resistance (and thus the heating characteristics) of the material depending on the radial distance of same from the center of the layer 508A. This permits use of a single voltage and current excitation to achieve the thermal edge loss compensation because the heater element will respond (heat) differently to the excitation voltage and current due to the differences in the resistance as a function of radial position.

The voltage and current excitation to the resistive heater layer 508A is provided by a power source (not shown) and controlled by the control unit to achieve temperature regulation (which may employ feedback control as discussed below). The control unit may be operable to program the lower bonding plate mechanism 500 to follow any desired heat-up or cool down ramp and dwell at any desired processing temperature. Terminals 552 (FIGS. 16-17) and terminals 508C (FIG. 18) permit electrical connections from the power source to the resistive heater layer 508A.

The thermal spreader 510 is in thermal communication with the heater disk 508 and is operable to integrate the heating profile presented by the heater disk 508 such that a more uniform presentation of heat is imparted to the glass substrate. The thermal spreader 510 may be both electrically and thermally conductive, as it is in direct contact with the glass substrate and facilitates heating the substrate and optionally applying a bonding voltage thereto. Again, the bonding voltage applied to the silicon donor wafer and the glass substrate may be achieved by: (i) applying a voltage potential to one of the silicon donor wafer and the glass substrate (while grounding the other); or by (ii) applying respective voltage potentials to both the silicon donor wafer and the glass substrate. Thus, the ability of the lower bonding plate mechanism 500 to impart a voltage potential (other than ground) to the glass substrate is an optional feature. If a bonding voltage potential (other than ground) is applied to the glass substrate by the lower bonding plate mechanism 500, such may be distributed substantially uniformly over the entire surface of the substrate, and may be in the range of about 1,750 volts DC.

Among the materials that may be employed to implement the thermal spreader 510, electrically conductive graphite is desirable, such as THERMAFOIL. Terminal 553 permits electrical connection from the high voltage power source (not shown) to the thermal spreader 510. The control unit may be operable to program the voltage level from the high voltage power source to attain the desired voltage (such as 1750 volts DC).

Reference is now also made to FIG. 19, which illustrates further structural and functional aspects of the lower bonding plate mechanism 500. As shown, the lower bonding plate mechanism 500 may optionally include an aperture 550 that permits access to the glass substrate during the bonding process, for example to impart a preload pressure and/or seed voltage to the substrate. It is noted that this optional feature need not be employed, but may provide advantageous operation as will be discussed below. When the aperture 550 is employed, a preferred use thereof is to permit a preload pressure and/or seed voltage to be applied to the glass substrate prior to application of the bonding voltage and full bonding pressure. As discussed above with respect to the upper bonding plate mechanism 400, the purpose of the preload pressure and seed voltage is to initiate anodic bonding in a localized area of the interface between the silicon donor wafer and the glass substrate prior to application of the bonding voltage, which facilitates anodic bonding across substantially the entire area of the interface. The seed voltage may be of the same or different magnitude as the bonding voltage, however, a lower or equal voltage is believed to be superior, e.g., about 750-1000 volts DC.

By way of example, a preload plunger 570 may be employed to achieve the aforementioned pre-charge functionality. The preload plunger 570 may be of substantially the same construction as the preload plunger 470 discussed above with respect to FIGS. 12A-12B. The preload plunger 570 is operable to engage the lower bonding plate mechanism 500 and extend through the aperture 550 thereof to electrically and mechanically communicate with the glass substrate. An electrode 584 of the preload plunger 570 engages the glass substrate at least to impart the seed voltage. A plunger of the preload plunger 570 is coaxially disposed about the electrode 584 and may alone (or in combination with the electrode 584) apply the preload pressure.

The lower bonding plate mechanism 500 may include one or more further apertures to permit the insertion of a thermocouple through the assembly such that it may thermally engage the heater disk 508 and provide a temperature feedback signal to the control unit (which permits tight temperature regulation of the heater disk 508 and the glass substrate). The structure and location of the aperture(s) for the thermocouples (and the thermocouple itself) may be substantially the same as those discussed above with respect to the upper bonding plate mechanism 400.

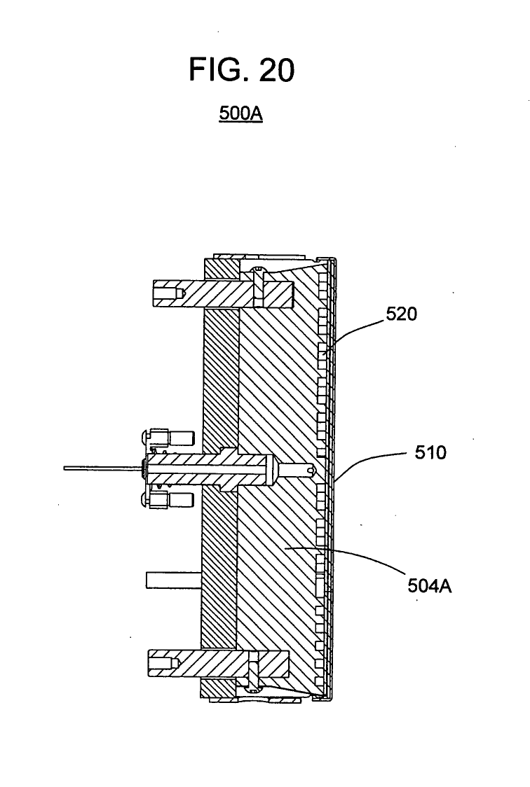

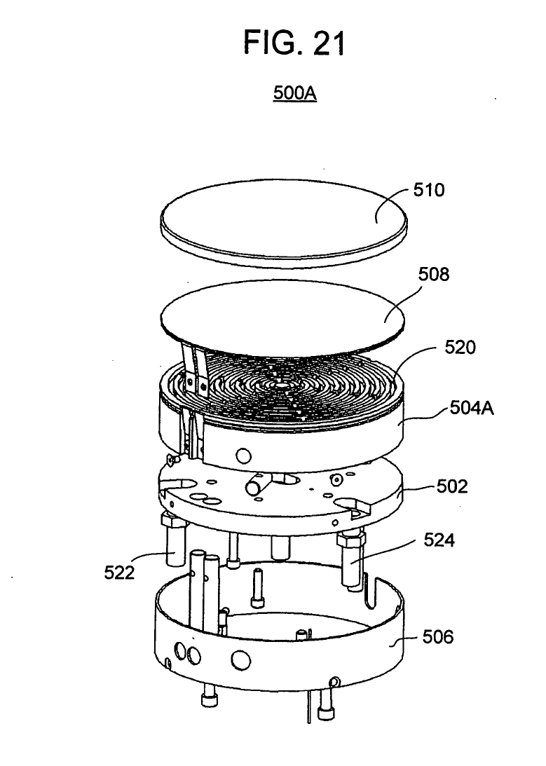

Reference is now made to FIGS. 20-21, which illustrate alternative functionality that may be employed in one or more further embodiments of a lower bonding plate mechanism. FIG. 20 is a cross-sectional view of the lower bonding plate mechanism 500A employing an active cooling feature. FIG. 21 is an exploded view of the lower bonding plate mechanism 500A of FIG. 20. In this embodiment, the insulator 504A of the lower bonding plate mechanism 500A includes one or more cooling channels 520 through which cooling fluid may flow when it is desirable to reduce the temperature of the SOG structure, specifically the glass substrate thereof. For example, the cooling channel 520 may extend spirally from a center of the insulator 504A toward the peripheral edge thereof. The channel(s) 520 may be machined into the surface of the insulator 504A. An inlet tube 522 is operable to introduce cooling fluid into the channels 520, while an outlet tube 524 is operable to remove the cooling fluid from the channels 520. A heat exchanger (not shown) may be employed to cool the cooling fluid prior to reintroducing same into the inlet tube 522. Active cooling may be achieved by controlling the temperature and flow rate of the cooling fluid through the channels 520 using the control unit. As illustrated in FIG. 13, appropriate fluid couplings 560 may be connected to the inlet tube 522 and the outlet tube 524 to permit the connection of a fluid source (not shown) to the lower bonding plate mechanism 500.

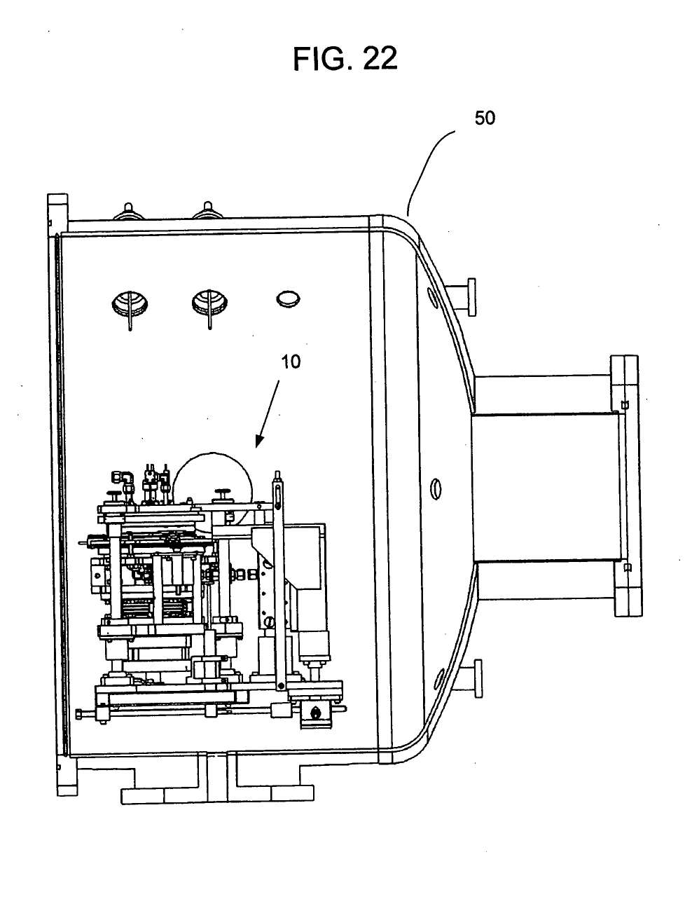

With reference to FIG. 22, the bonding apparatus 10 may be disposed in an atmospheric chamber to provide control of atmospheric conditions of the bonding environment, such as vacuum, gas atmospheres (such as hydrogen, nitrogen, etc.), and other conditions. Notably, the bonding apparatus 10 may operate in a non-vacuum atmosphere (e.g., an atmosphere that may include one or more oxidizing agents) without degradation of the various components thereof, especially the bonding plate mechanisms 400, 500.

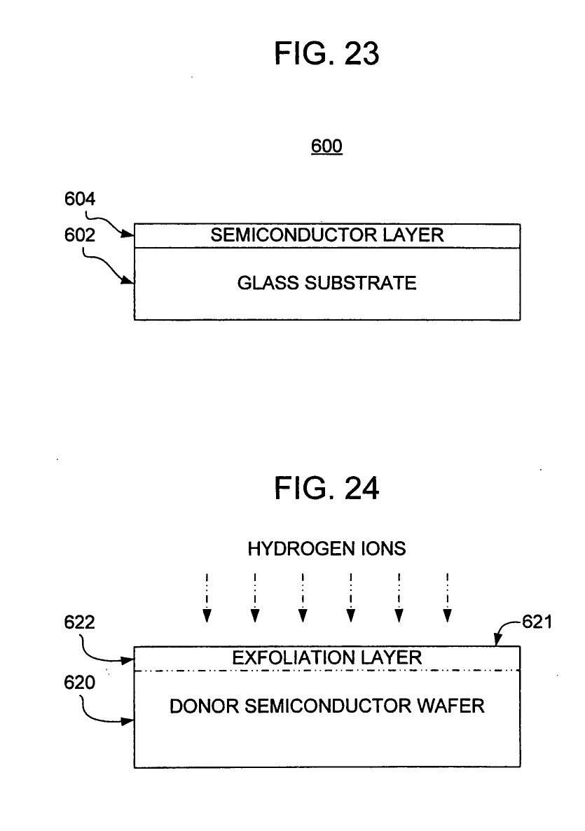

Further details regarding the operation of the bonding apparatus 10 will now be described with reference to FIGS. 23-27. FIG. 23 illustrates a final SOG structure 600, while FIGS. 24-27 illustrate intermediate structures thereof produced using one or more embodiments of the bonding apparatus 10. With reference to FIG. 24, prior to introducing materials into the bonding apparatus 10, an implantation surface 621 of a donor semiconductor wafer 620 is prepared, such as by polishing, cleaning, etc. to produce a relatively flat and uniform implantation surface 621 suitable for bonding to the glass or glass-ceramic substrate 602 (FIG. 23). For the purposes of discussion, the semiconductor wafer 620 may be a substantially single crystal Si wafer, although as discussed above any other suitable semiconductor conductor material may be employed.

An exfoliation layer 622 is created by subjecting the implantation surface 621 to an ion implantation process to create a weakened region below the implantation surface 621 of the donor semiconductor wafer 620, which defines the exfoliation layer 622. By way of example, the implantation surface 621 may be subject to hydrogen ion implantation, or other rare earth ions, such as boron, helium, etc. The donor semiconductor wafer 620 may be treated to reduce, for example, the hydrogen ion concentration on the implantation surface 621. For example, the donor semiconductor wafer 620 may be washed and cleaned and the implantation donor surface 621 of the exfoliation layer 622 may be subject to mild oxidation. The mild oxidation treatments may include treatment in oxygen plasma, ozone treatments, treatment with hydrogen peroxide, hydrogen peroxide and ammonia, hydrogen peroxide and an acid or a combination of these processes. It is expected that during these treatments hydrogen terminated surface groups oxidize to hydroxyl groups, which in turn also makes the surface of the silicon wafer hydrophilic. The treatment may be carried out at room temperature for the oxygen plasma and at temperature between 25-150° C. for the ammonia or acid treatments. Appropriate surface cleaning of the glass substrate 602 (and the exfoliation layer 622) may be carried out.

Assuming that the bonding apparatus 10 is in an initial orientation whereby the upper bonding plate mechanism 400 is rotated upward (as in FIG. 2), the donor semiconductor wafer 620 and the glass substrate 602 are inserted into the bonding apparatus 10. In this example, it is assumed that the glass substrate 602 is placed down and held via gravity to the lower bonding plate mechanism 500 and the donor semiconductor wafer 620 is placed atop the glass substrate 602. When application of a preload pressure and seed voltage to initiate bonding in a central region of the donor semiconductor wafer 620 and the glass substrate 602 is desired, the spacer mechanism 300 may be activated prior to the donor semiconductor wafer 620 being placed atop the glass substrate 602. As discussed with respect to FIGS. 6 and 14, the stepper motor 144 may rotate the gear 142, such that the swivel ring 304 rotates with respect to the mount ring 302, thereby driving the shims 330 to overlie peripheral portions of the glass substrate 602. The donor semiconductor wafer 620 may then be placed atop the shims 330 such that the shims 330 are interposed between the donor semiconductor wafer 620 and the glass substrate 602. Thus, the donor semiconductor wafer 620 and the glass substrate 602 will be spaced apart by the thickness of the shims 330.

Next, the upper bonding plate mechanism 400 is operable to rotate downward (via the open and close mechanism 200) such that the upper and lower bonding plate mechanisms 400, 500 are spaced apart in parallel orientation. More particularly, as discussed above with respect to FIG. 7, the jack 230 is actuated via manipulating the shaft 236, which results in lowering the shaft 232, the guide bushing 214, and the hinge plate 250. The lowering of the hinge plate 250 causes the mount plate 208 to pivot about the pivot linkage 258 such that the mount plate 208 and the upper bonding plate mechanism 400 tilt downward until the mount plate 208 engages the stops 259 of the hinge plate 250. At this point, the upper bonding plate mechanism 400 is in substantially parallel orientation with respect to the lower bonding plate mechanism 500. Continued downward movement of the hinge plate 250 results in the locks 246 engaging the ends 114A, 116A, 118A of the guide posts 114, 116, 118 of the lift and press mechanism 100 (FIG. 6). The operator may then engage the locks 246 into the guide posts 114, 116, 118 of the lift and press mechanism 100. The locks 246 ensure that upward pressure on the donor semiconductor wafer 620 and the upper bonding plate mechanism 400 may be countered by the mount plate 208 without exposing the lift and press mechanism 100 to excessive force.

The lift and press mechanism 100 may then impart coarse displacement of the lower bonding plate mechanism 500 (and the glass substrate 602 and donor semiconductor wafer 620) toward the upper bonding plate mechanism 400. As the electrode 484 of the preload plunger 470 extends below the thermal spreader 410 of the upper bonding plate mechanism 400, it contacts the donor semiconductor wafer 620 when the lift and press 100 mechanism coarsely displaces the lower bonding plate mechanism 500 toward the upper bonding plate mechanism 400. As the shims 330 of the spacer mechanism 300 prevent the peripheral edges of the donor semiconductor wafer 620 and the glass substrate 602 from touching one another, the preload plunger 470 will tend to bow the donor semiconductor wafer 620 such that the central portion thereof touches the glass substrate 602. Thus, application of the preload pressure and seed voltage may initiate the anodic bonding of the donor semiconductor wafer 620 and the glass substrate 602 before full pressure, temperature, and voltage is applied.

Following the initial bonding of the central portions of the donor semiconductor wafer 620 and the glass substrate 602, the spacer mechanism 300 may be commanded to withdraw the shims 330. The control unit may command the stepper motor 144 to rotate the gear 142 such that the swivel ring 304 rotates with respect to the mount ring 302, thereby withdrawing the shims 330 from between the donor semiconductor wafer 620 and the glass substrate 602. The shims 330 move in symmetric motion, which prevents any uneven friction loads as between the donor semiconductor wafer 620 and the glass substrate 602. Advantageously, if the bonding process is taking place in a vacuum, the bonding of the central portions of the donor semiconductor wafer 620 and the glass substrate 602 followed by withdrawal of the shims 330 permits any gasses from between the donor semiconductor wafer 620 and the glass substrate 602 to be evacuated. Thus, the likelihood of gas (e.g., air) impeding a proper bond between the donor semiconductor wafer 620 and the glass substrate 602 may be reduced.

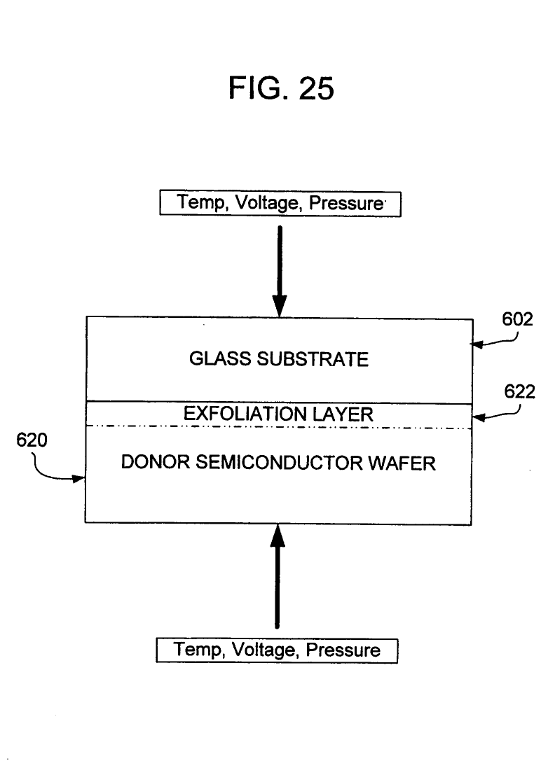

With reference to FIG. 25, the glass substrate 602 may be bonded to the exfoliation layer 622 using the anodic (electrolysis) process by bringing the glass substrate and the donor semiconductor wafer 620 into direct contact and subjecting them to the temperature, voltage and pressure using the bonding apparatus 10 as discussed above. The bonding apparatus 10 may operate under the control of the computer program (running on a processor of the control unit) to achieve the desired anodic bonding. Thus, it is contemplated that the computer program causes the various mechanisms of the bonding apparatus 10 to operate in the manner discussed herein to achieve the anodic bonding.

The exfoliation layer 622 of the donor semiconductor wafer 620, and the glass substrate 602 are heated under a differential temperature gradient. The glass substrate 602 may be heated to a higher temperature (via the lower bonding plate mechanism 500) than the donor semiconductor wafer 620 and exfoliation layer 622 (via the upper bonding plate mechanism 400). By way of example, the temperature difference between the glass substrate 602 and the donor semiconductor wafer 620 (and the exfoliation layer 622) may be anywhere between about 6° C. to about 200° C. or more. This temperature differential is desirable for a glass having a coefficient of thermal expansion (CTE) matched to that of the donor semiconductor wafer 620 (such as matched to the CTE of silicon) since it facilitates later separation of the exfoliation layer 622 from the semiconductor wafer 620 due to thermal stresses. The glass substrate 602 and the donor semiconductor wafer 620 may be taken to a temperature within about ±650° C. of the strain point of the glass substrate 602.

Mechanical pressure is also applied to the intermediate assembly. The pressure range may be: between about 1 to about 100 pounds per square inch (psi), between about 6 to about 50 psi, or about 20 psi. Although application of higher pressures, e.g., pressures at or above 100 psi are possible, such pressures should be used cautiously as they might cause breakage of the glass substrate 602. As discussed above with respect to FIGS. 4A, 4B, and 6, the donor semiconductor wafer 620 and the glass substrate 602 may contact one another under the controlled actuation of the lift and press mechanism 100. The second actuator 106 of the lift and press mechanism 100 raises the lower mount 108, the lower bonding plate mechanism 500, and the glass substrate 602 into position such that controlled heating and pressure between the donor semiconductor wafer 620 and the glass substrate 602 may be achieved.

A voltage is also applied across the intermediate assembly, for example with the donor semiconductor wafer 620 at a positive potential and the glass substrate 602 at a lower potential. The application of the voltage potential causes alkali or alkaline earth ions in the glass substrate 602 to move away from the semiconductor/glass interface further into the glass substrate 602. This accomplishes two functions: (i) an alkali or alkaline earth ion free interface is created; and (ii) the glass substrate 602 becomes very reactive and bonds strongly to the exfoliation layer 622 of the donor semiconductor wafer 620 with the application of heat at relatively low temperatures.

The pressure, temperature differential, and voltage differential are applied for a controlled period of time (e.g., approximately 6 hr or less). Thereafter, the high level voltage potential is brought to zero and the donor semiconductor wafer 620 and the glass substrate 602 are permitted to cool to at least initiate the separation of the exfoliation layer 622 from the donor semiconductor wafer 620. The cooling process may involve active cooling, whereby cooling fluid is introduced into one or both of the upper and lower bonding plate mechanisms 400, 500. In one or more embodiment, the active cooling profile may involve cooling the donor semiconductor wafer 620 and the glass substrate 602 at different profiles (e.g., cooling rates, dwells and/or levels) to impact the degree and quality of the exfoliation process.

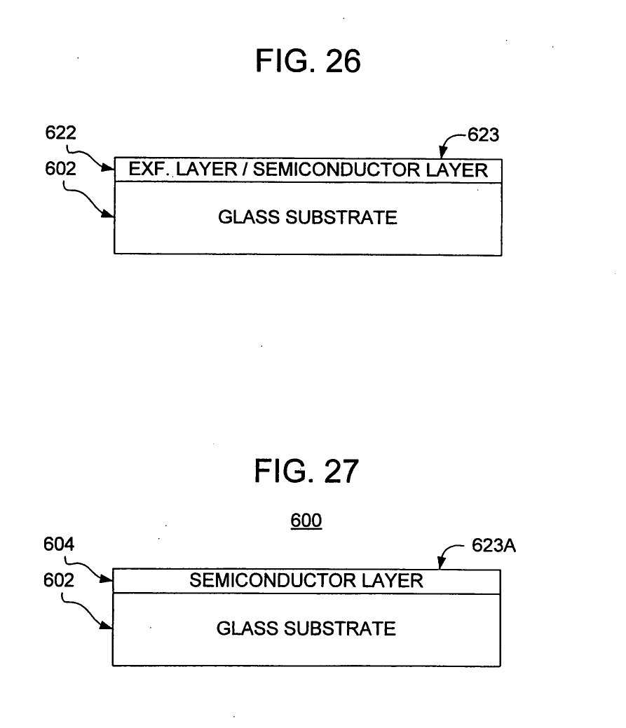

As illustrated in FIG. 26, after separation the resulting structure may include the glass substrate 602 and the exfoliation layer 622 of semiconductor material bonded thereto. In order to access this structure, the locks 246 are disengaged from the guide posts 114, 116, 118 and the jack 230 is actuated (for example, via applying a rotational force to the shaft 236), such that the shaft 232 may raises the guide bushing 214 and the hinge plate 250 applies a vertical force to the mount plate 208 by way of the block 260 and pivoting linkage 258 (FIGS. 6-7). The upper bonding plate mechanism 400 will, therefore, rise vertically away from the lower bonding plate mechanism 500 while maintaining a substantially parallel relationship thereto. A continued upward force on the mount plate 208 causes the upper bonding plate mechanism 400 to tilt upward in response to a rotational movement about the pivoting linkage 258. The intermediate structures of the SOG may then be extracted from the bonding apparatus 10.

Any unwanted or rough semiconductor material may be removed from the surface 623 via thinning and/or polishing techniques, e.g., via CMP or other techniques known in the art to obtain the semiconductor layer 604 on the glass substrate 602 as illustrated in FIG. 27.

It is noted that the donor semiconductor wafer 620 may be reused to continue producing other SOG structures 600.

In accordance with one or more further embodiments of the present invention, the bonding apparatus 10 may be employed to emboss micro-structures in a substrate, such as glass, glass ceramic, ceramic, etc. Conventional approaches to producing replicated patterns on substrates such as glass have employed additive processes (e.g. using UV cured polymers), or subtractive processes (e.g. chemical etching, Reactive Ion Etching). These convention approaches are not desirable in every application; indeed, polymer structures are very versatile but may not have the desired material properties, and etching methods can produce fine structures but are often very slow and costly. In accordance with one of more aspects of the present invention, however, patterns are impressed/embossed into a substrate from a master tool through heating. The master tool is constructed from material that is structurally rigid and has a melting point above that of the substrate. The tool and/or substrate are heated to level(s) where the substrate flows into micro-structures of the tool. Thereafter, the components are cooled and separated.

In one or more embodiments, the bonding apparatus 10 may be adapted to rapidly heat the tool and/or substrate (e.g., glass) allowing for high throughput. The aforementioned active cooling features, controlled compression features, vacuum atmosphere, etc. of the bonding apparatus 10 may also increase throughput.

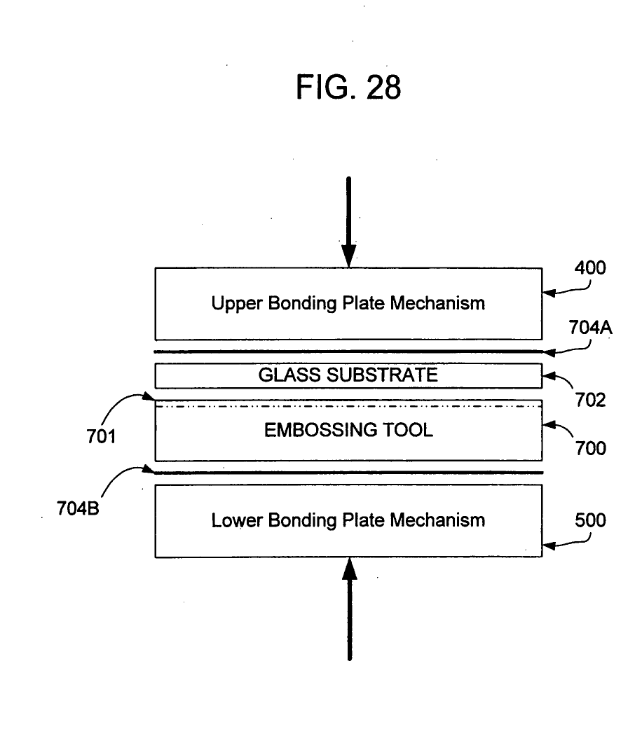

With reference to FIG. 28, the bonding apparatus 10 may be operable to receive a tool 700 having micro-structures 701 (e.g., in the nanometer scale) disposed on at least one surface thereof. The micro-structures on the tool 700 are the reverse of those desired to be embossed onto the substrate 702. By way of example, the tool 700 may be coupled to the lower bonding plate mechanism 500 and the substrate 702 (e.g., a glass substrate) may be placed atop the tool 700. Alternatively, the substrate 702 may be coupled to the lower bonding plate mechanism 500 and the tool 700 may be placed atop the substrate 702. In a further alternative embodiment, the tool 700 may be clipped or otherwise fastened to the upper bonding plate mechanism 400. Respective GRAFOIL gaskets 704A, 704B may be interposed between the upper/lower bonding plate mechanisms 400, 500 and the substrate 702/tool 700.

The bonding apparatus 10 may then be closed (as discussed above) and the temperature taken above the Tg of the glass substrate 702. The pattern or structure is thus transferred from the tool 700 to the glass substrate 702. The replication process may be conducted under high pressure from the controlled pressure features of the bonding apparatus 10 as described above. Alternatively, gravity and atmospheric pressure may be employed to facilitate the flow of the glass substrate 702 into the micro-structures 710 of the tool 700.

The tool 700 may be constructed of material that will not change structurally at temperatures elevated to, or above the flow temperature of the substrate 702, such as the Tg of a glass substrate. By way of example, fused silica may be employed to implement the tool 700. The micro-structures 701 may be formed in the tool 700 by Reactive Ion Etching (RIE). A surface treatment of the tool 700 and/or substrate 702 may also be employed, such as a diamond coating.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A bonding plate mechanism for use in anodic bonding of first and second material sheets together, the apparatus comprising:
a base including first and second spaced apart surfaces;
a thermal insulator supported by the second surface of the base and operable to impede heat transfer to the base;
a heating disk directly or indirectly coupled to the insulator and operable to produce heat in response to electrical power; and
a thermal spreader directly or indirectly coupled to the heating disk and operable to at least channel heat from the heating disk, and impart voltage, to the first material sheet,
wherein the heat and voltage imparted to the first material sheet are in accordance with respective heating and voltage profiles to assist in the anodic bonding of the first and second material sheets, and a thermal inertia of the bonding plate mechanism is relatively low such that heating of the first material sheet to a temperature of about 600° C. or greater is achieved in less than about one-half hour.

2. The apparatus of claim 1, wherein at least one of:
the thermal inertia of the bonding plate mechanism is such that heating of the first material sheet to a temperature of between about 1000° C. or greater is achieved in about two minutes; and
the thermal inertia of the bonding plate mechanism is such that cooling the first material sheet from about 600° C. or greater to about room is achieved in about 10 minutes or less.

3. The apparatus of claim 1, wherein one of the first and second material sheets a glass substrate and the other of the first and second material sheets is a donor semiconductor wafer.

4. The apparatus of claim 1, wherein the heating profile includes at least a peak temperature of the first material sheet of greater than about 600° C.

5. The apparatus of claim 1, wherein the heating profile includes at least a peak temperature of the first material sheet of between about 600° C. and 1000° C.

6. The apparatus of claim 1, wherein the heating profile includes at least a peak temperature of the first material sheet of greater than about 1000° C.

7. The apparatus of claim 1, wherein the voltage profile includes a peak voltage of the first material sheet of about 1750 volts DC.

8. The apparatus of claim 5, wherein the voltage profile includes at least a peak voltage of between about 100 volts DC and about 2000 volts of the first material sheet.

9. The apparatus of claim 1, wherein the pressure profile includes at least a peak pressure on the first material sheet of between about 1 pound per square inch (psi) and about 100 psi.

10. The apparatus of claim 1, wherein the pressure profile includes at least a peak pressure on the first material sheet of about 20 psi.

11. The apparatus of claim 1, wherein the thermal spreader is operable to conduct both heat and electrical current.

12. The apparatus of claim 11, wherein the thermal spreader is formed from electrically conductive graphite.

13. The apparatus of claim 1, wherein the thermal insulator is formed from a machinable glass ceramic material.

14. A bonding plate mechanism for use in anodic bonding of first and second material sheets together, the apparatus comprising:
a base including first and second spaced apart surfaces;
a heating disk directly or indirectly coupled to the base and operable to produce heat in response to electrical power, wherein the heater disk includes a plurality of heating zones operable to provide an edge loss temperature compensation feature,
wherein the heat imparted to the first material sheet is in accordance with a heating profile to assist in the anodic bonding of the first and second material sheets.

15. The apparatus of claim 14, wherein the heater disk includes a first heating zone at a central area thereof, and at least a second heating zone annularly disposed about the first heating zone.

16. The apparatus of claim 15, wherein the second heating zone operates to heat to a higher level than the first heating zone to compensate for edge loss.

17. The apparatus of claim 15, wherein:
the heating disk includes a first surface facing toward the thermal insulator and a second surface facing toward the thermal spreader;
the first heating zone is implemented using a first heating element that is disposed closer to the first surface of the heating disk than to the second surface thereof;
the second heating zone is implemented using a second heating element that is disposed closer to the second surface of the heating disk than to the first surface thereof.

18. The apparatus of claim 16, wherein the first and second heating zones are implemented using a single heating element that has at least one first electrical resistance in the first zone, and at least one second electrical resistance in the second zone, wherein the first resistance is greater than the second resistance.

19. The apparatus of claim 18, wherein:
the heating element is implemented using a material in which the resistance thereof is a function of a cross-sectional surface area thereof; and
an aggregate of the cross-sectional surface areas of the heating element in the first zone is lower than an aggregate of the cross-sectional surface areas of the heating element in the second zone.

20. The apparatus of claim 16, wherein the first and second heating zones are implemented using separate first and second heating elements, respectively, the first heating element having a higher resistance than the second heating element.

21. The apparatus of claim 14, further comprising at least one thermocouple in thermal communication with the heater disk and operable to produce one or more feedback signals indicative of the temperature of the heater disk.

22. A bonding plate mechanism for use in anodic bonding of first and second material sheets together, the apparatus comprising:
a heating disk including first and second spaced apart surfaces and operable to produce heat in response to electrical power;
a thermal spreader directly or indirectly coupled to the second surface of the heating disk and operable to at least channel heat from the heating disk, and impart voltage, to the first material sheet; and
at least one cooling channel in thermal communication with the first surface of the heater disk and being operable to carry cooling fluid to remove heat from the first material sheet through the thermal spreader and heater disk,
wherein the heat and voltage imparted to the first material sheet are in accordance with respective heating and voltage profiles to assist in the anodic bonding of the first and second material sheets, and the cooling imparted to the first material sheet is in accordance with a cooling profile to assist in separating, from the first material sheet, an exfoliation layer that has been bonded to the second material sheet.

23. The bonding plate mechanism of claim 22, further comprising a thermal insulator in thermal communication with the first surface of the heater disk and being operable to impede heat transfer from the heater disk, wherein the at least one cooling channel is integrally formed in the thermal insulator at an interface of the thermal insulator and the first surface of the heater disk.

24. The bonding plate mechanism of claim 22, further comprising a cooling plate having the at least one cooling channel formed therein such that it is in thermal communication with the first surface of the heater disk.

25. The bonding plate mechanism of claim 24, wherein the cooling plate is formed from boron nitride material.

26. The bonding plate mechanism of claim 24, further comprising:
a base having first and second spaced apart surfaces;
a thermal insulator supported by the second surface of the base, being in thermal communication with the cooling plate, and being operable to impede heat transfer from the heater disk to the base;
at least one inlet tube passing through the base and thermal insulator for carrying the cooling fluid into the at least one cooling channel; and
at least one outlet tube passing through the base and thermal insulator for carrying the cooling fluid out of the at least one cooling channel.

27. A heating plate mechanism for use in embossing a micro-structure on a material sheet, the apparatus comprising:
a base including first and second spaced apart surfaces;
a thermal insulator supported by the second surface of the base and operable to impede heat transfer to the base;
a heating disk directly or indirectly coupled to the insulator and operable to produce heat in response to electrical power;
a thermal spreader directly or indirectly coupled to the heating disk and operable to at least channel heat from the heating disk, and impart voltage, to the first material sheet; and
an embossing tool coupled to the thermal spreader and including micro-structures, disposed on at least one surface thereof,
wherein the heat imparted to the material sheet is sufficient to cause at least a portion of the material sheet, when in contact with the embossing tool, to flow into the micro-structures thereof.
